(19) United States
(12) Patent Application Publication
(10) Pub. No.: US 2024/0154032 A1
(43) Pub. Date: May 9, 2024

(54) EDGE TERMINATION STRUCTURE FOR A CHARGE BALANCED SEMICONDUCTOR DEVICE AND METHOD OF FABRICATING SAME

(71) Applicant: IDEAL SEMICONDUCTOR DEVICES, INC., Bethlehem, PA (US)

(72) Inventors: Philip Rutter, Bethlehem, PA (US); Stanislav Soloviev, Breinigsville, PA (US); David Jauregui, Bethlehem, PA (US)

(21) Appl. No.: 18/494,922

(22) Filed: Oct. 26, 2023

Related U.S. Application Data
(60) Provisional application No. 63/420,339, filed on Oct. 28, 2022.

(51) Int. Cl. H01L 29/78; H01L 29/06; H01L 29/66

(52) U.S. Cl. CPC H01L 29/7811; H01L 29/0619; H01L 29/66712

(57) ABSTRACT

An enhanced edge termination structure for use in a charge balanced semiconductor device is provided. The edge termination structure includes a plurality of edge termination trenches and a plurality of semiconductor mesa regions, each of the mesa regions being disposed between adjacent edge termination trenches. The edge termination trenches extend outwardly from an active region of the device on at least two adjacent sides of the active region when viewed in a plan view. The edge termination trenches are orthogonal to a corresponding edge of the active region from which they extend.

### CROSS-REFERENCE TO RELATED APPLICATION(S)

This application claims priority under 35 U.S.C. § 119 to Provisional Application No. 63/420,339, filed on Oct. 28, 2022, entitled “Enhanced Edge Termination for a Charge Balanced Semiconductor Device and Method of Fabrication Thereof,” the disclosure of which is incorporated by reference herein in its entirety for all purposes.

### BACKGROUND

The present invention relates generally to the electrical, electronic and computer arts, and, more particularly, to enhanced edge termination structures for use in a semiconductor device, and methods of fabricating such structures.

Vertically conducting semiconductor devices in an integrated circuit (IC) include an active region that is surrounded by an edge termination region. In such vertical devices, the edge of the die is invariably at the same or similar voltage potential as that of a bottom of the device due primarily to saw damage when the device is singulated, or lack of a blocking junction at the edge of the device. Therefore, an edge termination region is a critical part of the device design to ensure lateral blocking of voltage between the active region and edge of the die.

Traditional charge balance or superjunction devices sometimes employ concentric charge balance regions within the edge termination region. However, for charge balance regions that are electrically isolating, this scheme is limited to lower breakdown voltages (e.g., typically less than 150 volts). This is due primarily to the limitation of breakdown voltage of the insulating regions contained within the charge balance regions. Therefore, there is a need for edge termination schemes that allow higher voltage operations (e.g., greater than 150 volts) while utilizing electrically isolated charge balance structures.

### SUMMARY

The present invention, as manifested in one or more embodiments, beneficially provides an enhanced edge termination structure for use in a charge balanced semiconductor device. In one or more embodiments, the edge termination comprises a plurality of edge termination trenches that point outwards from an active region of the device on at least two adjacent sides of the active region; that is, the edge termination trenches are orthogonal to the edge of the active region. The outward-facing edge termination trenches further provide a continuous conduction path, which is advantageous.

In accordance with an embodiment of the invention, an edge termination structure for use in a charge balanced semiconductor device includes a plurality of charge balance edge termination trenches formed in an edge termination region of the semiconductor device. The change balance edge termination trenches extend outwardly from an active region of the semiconductor device toward the edge termination region on at least two sides of the active region. The charge balance edge termination trenches are orthogonal to an edge of the active region. The edge termination structure further includes a plurality of semiconductor mesa regions, each of the mesa regions being between adjacent charge balance edge termination trenches.

In accordance with an embodiment of the invention, a charge balanced semiconductor device comprises an active region including at least one active element therein, and an edge termination region at least partially surrounding the active region when viewed in a plan view. The edge termination region includes at least one edge termination structure comprising a plurality of charge balance edge termination trenches formed in an edge termination region of the semiconductor device. The change balance edge termination trenches extend outwardly from the active region of the semiconductor device toward the edge termination region on at least two sides of the active region. The charge balance edge termination trenches are orthogonal to an edge of the active region. The edge termination structure further includes a plurality of semiconductor mesa regions, each of the mesa regions being between adjacent charge balance edge termination trenches.

In accordance with another embodiment of the invention, a method of forming an edge termination structure in a charge balanced semiconductor device includes: forming a plurality of charge balance edge termination trenches in an edge termination region of the semiconductor device, the change balance edge termination trenches being configured to extend outwardly from an active region of the semiconductor device toward the edge termination region on at least two sides of the active region, the charge balance edge termination trenches being orthogonal to an edge of the active region; and forming a plurality of semiconductor mesa regions, each of the mesa regions being between adjacent charge balance edge termination trenches.

In accordance with yet another embodiment of the invention, a method of forming a charge balanced semiconductor device includes: forming an active region including at least one active element therein; and forming an edge termination region at least partially surrounding the active region when viewed in a plan view, the edge termination region including at least one edge termination structure. In forming the edge termination structure, the method further includes: forming a plurality of charge balance edge termination trenches in an edge termination region of the semiconductor device, the change balance edge termination trenches being configured to extend outwardly from an active region of the semiconductor device toward the edge termination region on at least two sides of the active region, the charge balance edge termination trenches being orthogonal to an edge of the active region; and forming a plurality of semiconductor mesa regions, each of the mesa regions being between adjacent charge balance edge termination trenches.

As may be used herein, “facilitating” an action includes performing the action, making the action easier, helping to carry the action out, or causing the action to be performed. Thus, by way of example only and without limitation, in the context of a semiconductor fabrication methodology, steps performed by one entity might facilitate an action carried out by another entity to cause or aid the desired action(s) or steps to be performed. For the avoidance of doubt, where an actor facilitates an action by other than directly performing the action, it is assumed that the action is nevertheless performed by some entity or combination of entities.

Techniques of the present invention can provide substantial beneficial technical effects. By way of example only and without limitation, edge termination structures and/or methods of fabricating edge termination structures according to embodiments of the invention may provide one or more of the following advantages:
achieves improved stability of device breakdown voltage;
provides a direct conduction path to the active area surface for all edge termination regions, so that there are no floating regions in the device;
provides a direct connection of charge balance regions to the active area surface;
compatible with other edge termination features that are used to improve an effectiveness of edge termination structures, including, for example, inner field plates, outer field plates, junction termination extensions (JTEs), variable lateral diffusion (VLD), and charged or resistive layer on surface;
increases the breakdown voltage of the edge termination region.

These and other features and advantages of the present invention will become apparent from the following detailed description of illustrative embodiments thereof, which is to be read in connection with the accompanying drawings.

### BRIEF DESCRIPTION OF THE DRAWINGS

Non-limiting and non-exhaustive embodiments of the present invention will be described with reference to the following drawings which are presented by way of example only, wherein like reference numerals (when used) indicate corresponding elements throughout the several views unless specified otherwise, and wherein:

FIGS. 1A and 1B conceptually depict at least a portion of an exemplary integrated circuit (IC) die in which aspects of the present invention can be implemented; FIG. 1A is a top plan view of the IC die, and FIG. 1B is a cross-sectional view depicting a portion of the IC die shown in FIG. 1A taken along line A-A′;

FIG. 2 is a top plan view depicting at least a portion of an IC die that includes concentric charge balance structures in its edge termination region;

FIGS. 3A-3E are cross-sectional views each depicting at least a portion of exemplary p-n diodes that use electrical isolation in their charge balance regions;

FIG. 4 is a top plan view depicting at least a portion of an exemplary charge balanced IC device having an enhanced edge termination structure, according to one or more embodiments of the present invention;

FIG. 5 is a top floor plan view depicting at least a portion of an exemplary IC device, according to one or more embodiments of the invention;

FIG. 6, a top plan view of at least a portion of an illustrative corner structure for use in an edge termination region of a charge balanced IC device is shown, according to one or more embodiments of the present invention;

FIGS. 7A and 7B are top plan and cross-sectional views, respectively, depicting at least a portion of an exemplary corner structure for use in an edge termination region of a charge balanced IC device which incorporates other features therein, according to one or more embodiments of the present invention;

FIG. 8 is a top plan view depicting at least a portion of an illustrative corner structure for use in an edge termination region of a charge balanced IC device, according to one or more embodiments of the present invention;

FIG. 9 is a top plan view depicting at least a portion of an exemplary edge termination region in an IC device that includes a junction termination extension (JTE) implant that employs variable lateral diffusion (VLD), according to one or more embodiments of the present invention;

FIG. 10 is a top plan view depicting at least a portion of an illustrative corner structure for use in an edge termination region of a charge balanced IC device, according to one or more embodiments of the present invention;

FIGS. 11A-11D are top plan views conceptually depicting at least a portion of an illustrative charge balanced IC device utilizing different configurations for forming the break between active region and edge termination region trenches, according to embodiments of the present invention;

FIGS. 12A and 12B are top plan views depicting an exemplary charge balanced IC device having active region trenches and edge termination region trenches with different pitches, according to one or more embodiments of the present invention;

FIGS. 13A and 13B are top plan and cross-sectional views, respectively, depicting at least a portion of an exemplary charge balanced IC device, according to one or more embodiments of the present invention;

FIG. 14 is a top plan view depicting at least a portion of an exemplary charge balanced IC device including mesa width variation and slotted trench features, according to one or more embodiments of the present invention;

FIG. 15 is a top plan view conceptually depicting at least a portion of an exemplary charge balanced IC device utilizing multiple pitch variations in the exemplary edge termination region, according to one or more embodiments of the present invention;

FIG. 16 is a top plan view depicting at least a portion of an exemplary charge balanced IC device, according to one or more embodiments of the present invention;

FIGS. 17A and 17B depict two different configurations of exemplary corner structures that employ edge termination region trenches that extend at a tangent to a radius of curvature of the corner structure, according to embodiments of the present invention;

FIG. 18 is a top plan view illustrating at least a portion of an exemplary parquet corner structure utilized in an edge termination region of a charge balanced IC device, according to one or more embodiments of the present invention;

FIG. 19 is a top plan view depicting at least a portion of an exemplary extended parquet cornet structure utilized in an edge termination region of a charge balanced IC device, according to one or more embodiments of the present invention; and

FIG. 20 is a top plan view depicting at least a portion of an exemplary charge balanced IC device having an enhanced edge termination structure, according to one or more embodiments of the present invention.

It is to be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION

Principles of the present invention, as manifested in one or more embodiments thereof, will be described herein in the context of illustrative edge termination structures for use in a charge balanced semiconductor device, and methods for fabricating such structures, which have beneficial application, for example, in a power device or power system environment for providing direct current (DC)-DC or alternating current (AC)-DC conversion. It is to be appreciated, however, that the invention is not limited to the specific structures and/or methods illustratively shown and described herein. Rather, it will become apparent to those skilled in the art given the teachings herein that numerous modifications can be made to the embodiments shown that are within the scope of the claimed invention. That is, no limitations with respect to the embodiments shown and described herein are intended or should be inferred.

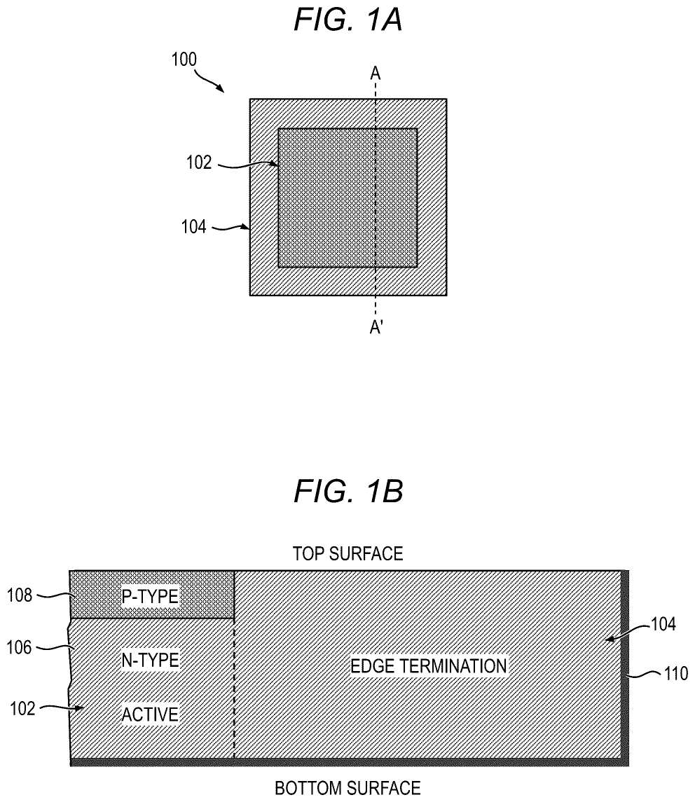

FIGS. 1A and 1B conceptually depict at least a portion of an exemplary integrated circuit (IC) die 100 in which aspects of the invention can be implemented; FIG. 1A is a top plan view of the IC die 100, and FIG. 1B is a cross-sectional view depicting only a portion of the IC die 100 shown in FIG. 1A taken along line A-A′. With reference to FIGS. 1A and 1B, the IC die 100, which may include one or more vertically conducting devices, includes an active region 102 that is surrounded by an edge termination region 104. In this embodiment, the active region 102 comprises an n-type material 106 in which p-type material 108 is preferably formed, although embodiments of the invention are not limited to this specific arrangement. As will be known by those skilled in the art, n-type material 106 can be formed by doping a semiconductor material (e.g., silicon) with an n-type (donor) dopant element, such as, for example, phosphorous, arsenic, etc., and p-type material 108 can be formed by doping the semiconductor material with a p-type (acceptor) dopant element, such as, for example, boron, at a prescribed doping concentration.

In vertically conducting devices, an edge 110 of the die 100 is invariably at the same or similar voltage potential as that of a bottom surface of the device, due primarily to saw damage when the device is singulated or lack of a blocking junction at the edge of the device. Therefore, there is a need to not only block voltages between the top and bottom surfaces of the vertical device, but also to block voltages laterally between the active region 102 of the device and edge 110 of the die; the edge termination region 104 is the region in the device that provides this lateral voltage blocking capability.

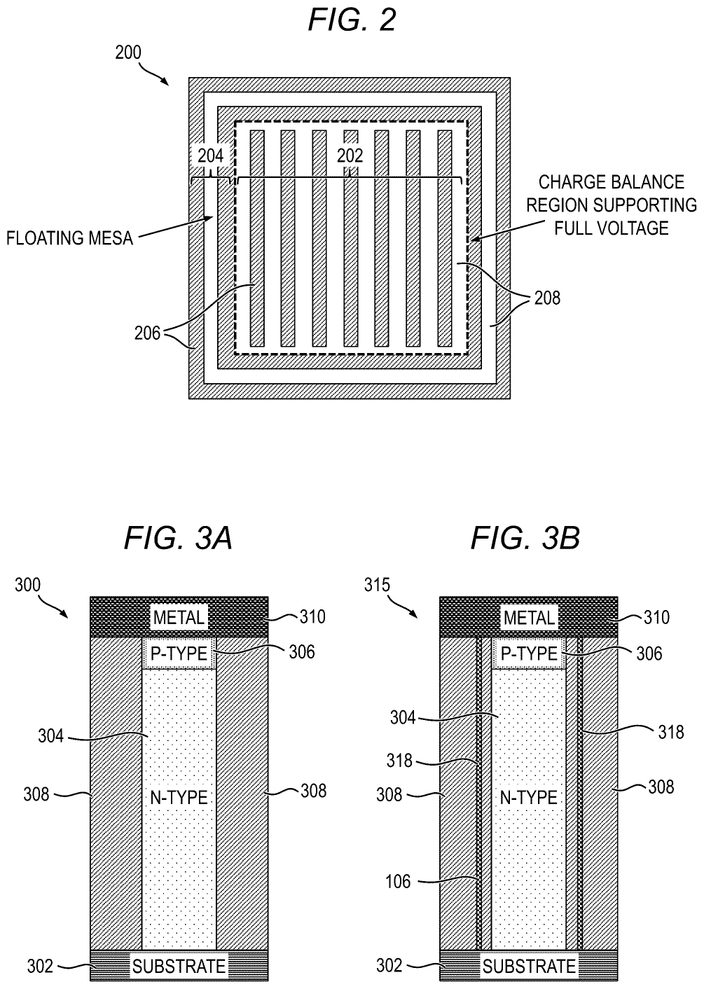

Edge termination structures that employ charge balance regions that include some type of electrical isolation are particularly challenging, as the electrical isolation can undesirably restrict the flow of current needed to establish the required change in voltage between the active region 102 and edge termination region 104 of the die. For example, FIG. 2 is a top plan view depicting at least a portion of an illustrative IC die 200 that includes concentric charge balance structures in its edge termination region. More particularly, the IC die 200 includes an active region 202 and an edge termination region 204 around the periphery of the IC die surrounding the active region. The active region 202 includes a plurality of electrically isolating charge balance regions 206 alternating with mesa regions 208 which, together, create an overall charge balanced active region. The term “mesa,” as used herein, is intended to refer to an area of semiconductor material (e.g., n-type and/or p-type) between charge balance regions wherein active devices (e.g., diodes, transistors, etc.) are formed. In one or more embodiments, the charge balance regions 206 are preferably formed as trenches in the IC die 200 that may be filled with a high-dielectric constant (high-k) material (e.g., hafnium oxide, PZT, etc.). Likewise, the IC die 200 achieves charge balance in the edge termination region 204 by including concentric charge balance regions 206 and alternating semiconductor mesa regions 208.

If electrically “floating” regions are created due to the electrical isolation of these charge balance and mesa regions 206, 208, then their potentials will be determined initially by capacitive coupling, and in steady state, due primarily to leakage current paths, each of these regions will have an indeterminate voltage over time. The voltage at the surface of these “floating” regions will converge in time to the same potential as the bottom surface of the die to which they remain connected.

Traditionally, by using concentric charge balance regions 206 in the edge termination region 204, electrically isolated charge balance regions would result in the full voltage being applied across the first charge balance region, rather than being distributed across all structures in the edge termination region; this first edge termination mesa 208 is floating (i.e., not directly connected to the surface of the active region surface), and will therefore drift to the same potential as the bottom surface of the die. Hence, there is a limitation for charge balance regions that have electrical isolation where the maximum blocking voltage is limited to the blocking voltage of a single charge balance region.

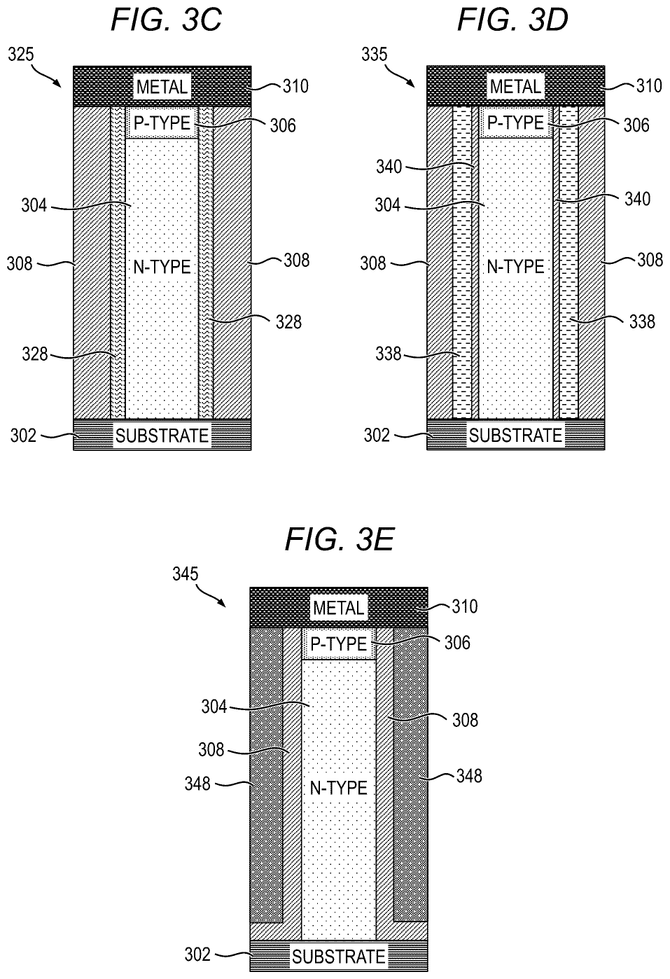

Advantageously, embodiments of the present invention provide a means for achieving charge balance in the edge termination region while simultaneously ensuring the flow of currents (e.g., capacitive and leakage currents) required to make a functioning edge termination structure, as will be described in further detail herein below. Illustrative device structures in which aspects of the invention are particularly well-suited include, but are not limited to, the devices shown in FIGS. 3A-3E, each of which are cross-sectional views depicting at least a portion of exemplary p-n diodes that use electrical isolation in their charge balance regions. This structure is also applicable to Schottky diodes, metal-oxide semiconductor field-effect transistors (MOSFETs), and other vertical devices.

By way of example only and without limitation, FIG. 3A shows an exemplary p-n diode 300 including a substrate 302 preferably comprising a semiconductor material (e.g., silicon). An n-type semiconductor material layer 304 is formed on an upper surface of the substrate 302, and a p-type semiconductor material layer 306 is formed on an upper surface of the n-type material layer. Together, the n-type material layer 304 and p-type material layer 306 forms an active p-n junction of the diode 300. An insulting layer 308, preferably having a high-dielectric constant (high-k), surrounds the n-type material layer 304 and p-type material layer 306. The insulating layer 308 may be formed using standard dielectric deposition or growth techniques. In some embodiments, for example, the insulating layer 308 is formed as a trench in which insulating material is grown or deposited. A metal layer 310 is formed on an upper surface of the p-type material layer 306. The metal layer 310 provides electrical connection to the p-type material layer 306, while electrical connection to the n-type material layer 304 is provided via the substrate 302. In the p-n diode 300, the charge balance functionality is provided by the high-k insulating layer 308.

FIG. 3B illustrates an exemplary p-n diode 315 which is similar to the p-n diode 300 shown in FIG. 3A, except that the insulating layer 308 surrounding the n-type and p-type material layers 304 and 306, respectively, includes a high-resistance conductive layer 318 formed therein between the metal layer 310 and the substrate 302. This high-resistance conductive layer 318, which is isolated from the p-n junction via the insulating layer 308, forms a charge balance region in the p-n device 315.

FIG. 3C depicts an exemplary p-n diode 325 wherein the charge balance region is formed as a diffusion layer 328 surrounding the n-type and p-type material layers 304 and 306, respectively, between the metal layer 310 and the substrate 302. The diffusion layer 328 can be formed as a trench in which p-type material (or n-type material, depending on the application) is formed on a sidewall of the trench, proximate to the mesa of n-type and p-type materials 304, 306 forming the active p-n junction, such as by implantation, diffusion, deposition/growth, etc., after which at least a portion of the remaining trench is filled with insulating material 308; the trench may also be left with voids, in other embodiments.

In FIG. 3D, an exemplary p-n diode 335 is shown having a charge balance region that includes a fixed charge layer 338 disposed between the metal layer 310 and the substrate 302. The fixed charge layer 338 can be formed as a trench in which material having a fixed charge (e.g., alumina (Al₂O₃)) is formed on a sidewall of the trench, such as by implantation, diffusion into an existing layer, by deposition (e.g., atomic layer deposition (ALD)), growth, etc., after which at least a portion of the remaining trench is at least partially filled with insulating material 308. The fixed charge layer 338 is electrically isolated from the p-n conduction region (pillar) 306/304 by an insulating layer 340. In other embodiments in which the charged layer is electrically insulating (e.g., alumina), layer 340 is removed and the charged layer 338 is in direct contact with the p-n conduction region 306/304. For the illustrative device 335 shown in FIG. 3D where the drift region is n-type, the fixed charge layer 338 is negative. This fixed charge layer 338 induces a p-type inversion layer along the side of the charge balance trench as the negative fixed charge “balances” with positively charged free carriers (holes). As reverse bias is applied and the mesa (p-n pillar) depletes, the fixed charge will no longer balance with holes (which are repelled by the reverse bias) but will instead “balance” with the positively charged ionized donors within a depletion region formed in the device.

FIG. 3E shows an exemplary p-n diode 345 which includes a field plate. More particularly, the charge balance region comprises an isolated conductor 348 acting as a field plate which is connected to the metal layer 310. The conductor 348 runs along the n-type and p-type material layers, 304 and 306, respectively, but is electrically isolated from the p-n conduction region and the substrate 302 via the insulating layer 308. The charge balance region may be formed, in one or more embodiments, as a trench having an insulating layer 308 (e.g., typically silicon dioxide) formed on sidewall and bottom surfaces, such as by deposition or growth, and then filling the remaining trench opening with the conductor 348. The term “filling” (or “fill,” or like terms), as may be used herein, is intended to refer broadly to either completely filling a defined space (e.g., charge balance region trench) or partially filling the defined space; that is, the defined space need not be entirely filled but may, for example, be partially filled or have voids or other spaces throughout.

It is to be appreciated that although several exemplary p-n diode configurations are depicted in FIGS. 3A-3E, embodiments of the invention are not restricted to these configurations. Rather, embodiments of the invention contemplate various other ways to create electrically isolating charge balance regions in addition to those shown, as will become apparent to those skilled in the art given the teachings herein. Stated more broadly, embodiments of the invention are directed to any charge balance region that includes an insulating layer for preventing current flow across the charge balance region. Aspects according to one or more embodiments of the invention may also be directed to non-isolating structures, for example a standard superjunction device having p-type and n-type columns; in such an embodiment, the charge balance trench may be formed entirely of p-type material.

In FIGS. 3A-3E, although unlikely in practice, it is contemplated that the charge balance regions only extend to the start of the p-type layer 306 (or close to it). Moreover, when the trench is filled with an insulator, this insulator may comprise more than one different insulating film, that may also vary at different locations in the trench, and could include a void. It is also to be appreciated that the charge balance regions do not necessarily need to extend vertically all the way to the substrate 302. In some embodiments, for example, the charge balance trench may extend along the p-n active pillar and end before the substrate 302 in the device.

As previously stated, each of the vertical power devices illustrated in FIGS. 3A-3E use electrical isolation in their charge balance regions, including those devices that employ charge balance/superjunctions in their edge termination schemes. However, such electrically isolated charge balance regions would undesirably result in the full voltage being applied across the first charge balance region rather than being distributed across the full edge termination region. For such structures that employ electrically isolated charge balance regions, embodiments of the invention provide a modified approach which beneficially removes the problem of a floating mesa with no path for current to flow in the edge to the top surface of the active region.

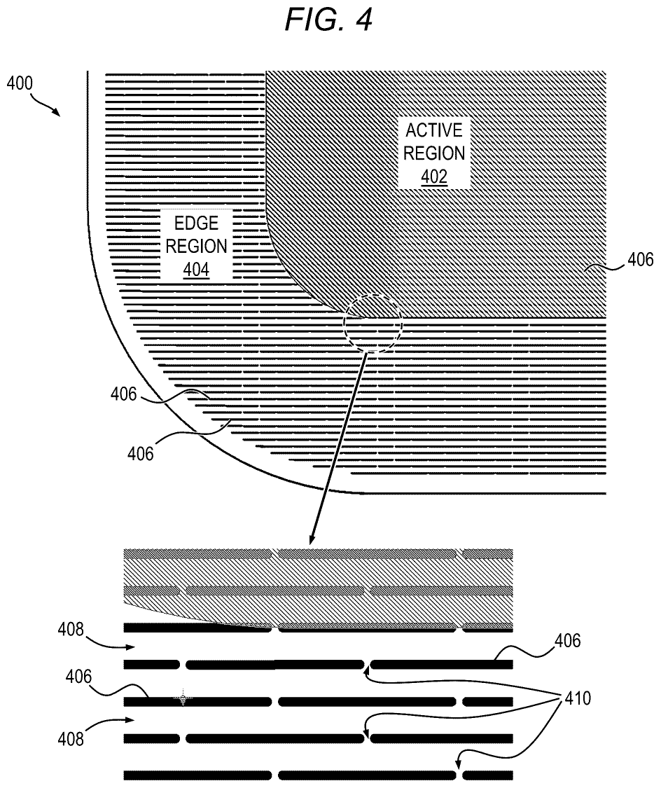

FIG. 4 is a top plan view depicting at least a portion of an exemplary charge balanced IC device 400 having an enhanced edge termination structure, according to one or more embodiments of the invention. As shown in FIG. 4, the IC device 400 includes an active region 402 in which one or more active electrical devices or other active elements may be formed, and an edge region 404 surrounding the active region. The term “surrounding” (or “surrounds,” or like terms) as may be used herein is intended to broadly refer to an element, structure or layer that extends around, envelops, encircles, or encloses another element, structure or layer on all sides, although breaks or gaps may also be present. Thus, for example, a material layer having voids therein may still “surround” another layer which it encircles.

In this illustrative embodiment, the active region 402 includes a plurality of charge balance regions 406, which may be implemented using trenches. The trenches 406 extend horizontally and continuously, in the same orientation, through the active region 402 and into the edge region 404. In one or more embodiments, each of the charge balance trenches 406 preferably comprises a high-k insulating material (although the charge balance trenches may alternatively comprise a semiconductor material, in some embodiments) and is spaced laterally from adjacent trenches by a semiconductor mesa 408 (e.g., in a manner consistent with the arrangement of the trenches 206 and mesas 208 shown in FIG. 2) to achieve charge balance in the device 400; the trenches 406 are electrically isolated from the mesas 408 between adjacent trenches.

As previously stated, for structures employing conventional trenches that are continuous in nature with electrical isolation, this arrangement creates floating mesas with no path for current flow in the edge region 404 to the top surface of the active region 402, which is problematic. A solution to this problem, according to one or more embodiments of the invention, is to incorporate slots (or gaps or the like) 410 in the trenches 406 which facilitates current flow and ensures that there is a current path for all parts of the edge region 404 to the top surface of the active region 402. More particularly, the slots 410 may be configured to provide an electrical connection between prescribed points, regions or areas in the edge region 404 and the top surface of the active region 402. Preferably, the slots 410 in the trenches 406 are staggered, such that the slots formed in one trench do not align laterally (i.e., in a plane parallel to an upper surface of the IC device 400) with slots in an adjacent trench. Since the trenches 406 may affect charge balance, forming the trenches with offset slots may provide a more uniform structure and hence improved breakdown voltage in the IC device 400. Forming trenches with offset slots may have an added effect of increasing resistance in the edge termination region.

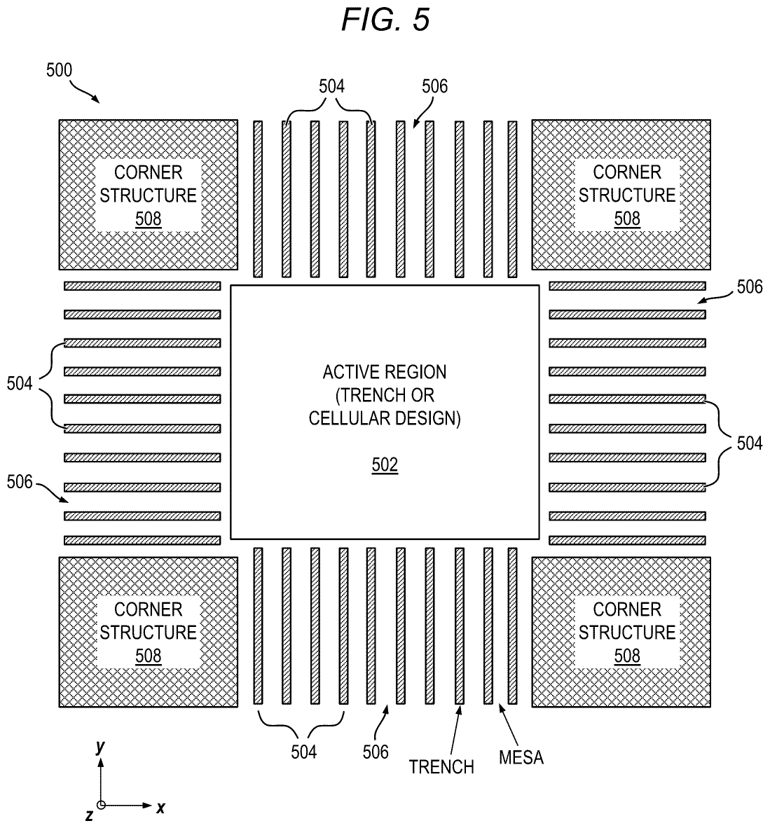

FIG. 5 is a top plan view depicting at least a portion of an exemplary IC device 500, according to one or more embodiments of the invention. The IC device 500 includes an active region 502, which may comprise a trench or cellular design, and an edge region which encompasses everything outside of the active region 502. Medial (i.e., middle or center) portions of the edge region (i.e., between corners of the IC device 500) may include a plurality of charge balance regions, which may be implemented as charge balance trenches 504 in one or more embodiments, with adjacent trenches 504 being separated from one another by a mesa 506 therebetween. In one or more embodiments, each of the mesas 506 in the edge region preferably comprises semiconductor material (n-type and/or p-type material), and each of the trenches 504 in the edge region comprises material (e.g., high-k insulating layer, etc.) having either an inherent charge or which may induce the formation of a charged layer (e.g., inversion layer, as in FIG. 3D) proximate to the semiconductor mesa 506 to provide charge balancing in the device, as previously explained. In one or more embodiments, each of at least a subset of the trenches 504 may be at least partially filled with an insulating material, such as, for example, alumina, although embodiments of the invention are not limited thereto.

In an edge termination scheme according to one or more embodiments of the invention, the trenches 504 are arranged so that they are orthogonal to an edge of the active region 502 on all four sides of the active region; that is, the trenches 504 in the medial portions of the edge region are arranged so that they extend outwardly in an x-axis or y-axis direction (i.e., parallel to an upper surface of a substrate (not explicitly shown) in which the IC device 500 is formed) from the active region 502 toward the edge region. In other embodiments, the trenches 504 may be configured to extend outwardly from the active region 502 toward the edge region on at least one side (i.e., one, two, three or four sides) of the active region 502, the trenches 504 being orthogonal to an edge of the active region 502.

The outward-facing trenches 504 may provide a continuous current conduction path for mesa regions 506 in the IC device 500, which can be advantageous. For example, in edge termination schemes like the illustrative structure 325 shown in FIG. 3C that uses a p-type diffusion layer 328 formed along sidewalls of the trench, or the illustrative structure 335 shown in FIG. 3D that includes a charged dielectric layer (e.g., alumina) that induces an inversion layer along the trench, the outward-facing trenches are beneficial since they allow for effective depletion and rebuilding of the p-type regions during switching.

The IC device 500 may include one or more corner structures 508 formed, each of the corner structures 508 being disposed in a corresponding corner of the edge region (i.e., between adjacent sides of the IC device 500), such that the plurality of trenches 504 in each medial portion of the edge region are between two corner structures 508. Each of the corner structures 508, in one or more embodiments, comprises a plurality of trenches (not explicitly shown, but implied), which may be consistent with the trenches 504. The trenches in the corner structures are preferably arranged differently compared to the trenches 504 in the medial portions of the edge region, however a similar design philosophy of ensuring a continuous conduction path for all n-type silicon regions (for devices employing an n-type epitaxial layer) between the active region 502 and the edge of the IC device 500 is preferably followed. It is to be appreciated that embodiments of the invention contemplate numerous edge termination designs for the corner structures 508, some examples of which will be described in further detail herein below.

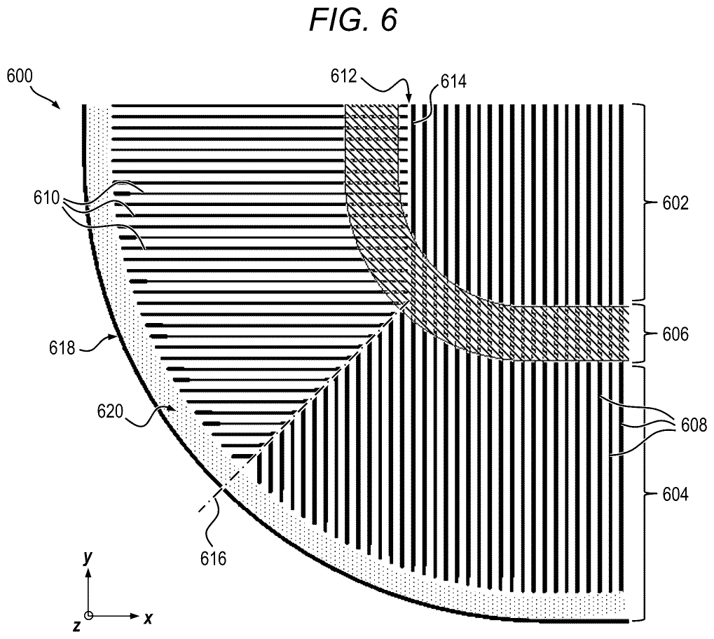

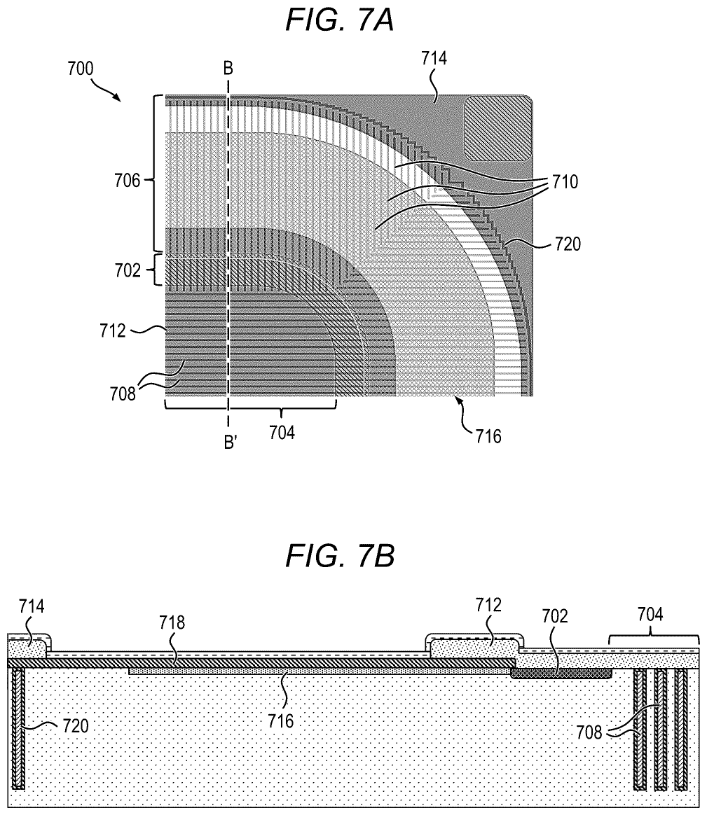

Optionally, the IC device 500, in some embodiments, may include a boundary trench (i.e., peripheral isolation trench) surrounding a periphery of the device (not explicitly shown, but implied), consistent with the arrangement shown in FIG. 6 and described in detail herein below. This boundary trench can be beneficial, and a gap between the edge termination region trenches 504 and this peripheral isolation trench can be critical.

Some benefits of edge termination designs according to one or more embodiments of the present disclosure may include improved stability of breakdown voltage in the device due, at least in part, to the elimination of floating mesas, since all edge termination regions may have a direct conduction path to the active area surface (e.g., anode for a diode, source for a MOSFET), and (for some embodiments) a direct connection of the charge balance regions to the active area surface, and hence any p-type region created by the charge balance region. Conventional edge termination schemes cannot achieve these benefits. Moreover, edge termination designs according to one or more embodiments of the invention are compatible with other known edge termination features that are used to improve the effectiveness of edge termination structures, including the use of inner field plates, outer field plates, junction termination extensions (JTEs), variable lateral diffusion (VLD), and the inclusion of a charged or resistive layer on the surface of the edge termination structure, among other schemes.

By way of example only and without limitation or loss of generality, FIGS. 6-19 conceptually depict various edge termination arrangements for use in a charged balanced semiconductor device formed in accordance with embodiments of the present invention. With reference initially to FIG. 6, a top plan view of at least a portion of an illustrative corner structure 600 for use in an edge termination region of a charge balanced IC device is shown, according to one or more embodiments of the invention. The device includes an active region 602, in which one or more electrical devices are formed, and an edge termination region 604. In this embodiment, a p-type guard ring 606 (for a Schottky device) may define or delineate a transition or boundary between the active region 602 and edge termination region 604. In general, the guard ring 606 may be of a first conductivity type (e.g., p-type).

If the device shown in FIG. 6 was a PN diode, then an edge of the guard ring 606 may form an edge of the p-type diffusion in the active region 602 of the device. Although the guard ring 606 may function as at least part of an active device (e.g., a diode), it is generally not considered to be part of the active region 602. In the example embodiment of a Schottky device, or a MOSFET device, the guard ring 606 represents an area that behaves differently, electrically speaking, from that of the active region 602. Generally, any region that is different from the active cellular array (i.e., active region 602) is considered to be a non-active region, and if this non-active region is disposed around a periphery of the device, then it may be considered to be an edge termination region (e.g., 604).

The corner structure 600 may be configured to provide an interface between facing end portions of a first subset of charge balance edge termination trenches (i.e., vertical trenches) 608 extending in a first direction (e.g., y-axis direction) from a first side of the active region 602 and corresponding end portions of a second subset of charge balance edge termination trenches (i.e., horizontal trenches) 610 extending in a second direction from a second side of the active region 602 adjacent to the first side of the active region. Stated differently, the corner structure is configured to provide an interface region in which corresponding end portions of the trenches 608 and 610 extending outwardly from adjacent sides of the active region 602 meet.

As apparent from FIG. 6, the active region 602 may include the plurality of vertical trenches 608 (i.e., oriented in a y-axis direction) which extend continuously from the active region 602, through the guard ring 606 and into a portion of the edge termination region 604. The plurality of horizontal trenches 610 (i.e., extending in an x-axis direction) are separate and orthogonal to the vertical trenches 608, in this illustrative embodiment. Optionally, in some embodiments, there may be a small gap 612 (e.g., about 0.5 μm-3 μm), preferably less than the width of a mesa, between the horizontal trenches 610 and a first vertical trench 614 of the plurality of vertical trenches 608, the first vertical trench 614 being disposed in the active region 602, in one or more embodiments. Although shown in FIG. 6 as being disposed within the active region 602, it is to be appreciated that in some embodiments, the gap 612, as well as the first vertical trench 614, may be disposed within the guard ring 606. This gap 612 may provide more uniform charge balance and easier processing of the IC device in which the corner structure 600 is formed.

In the corner structure 600 of the edge termination region 604, facing ends of the horizontal trenches 610 and the vertical trenches 608 may meet at an interface represented by line 616. In some embodiments, the interface 616 between facing end portions of the trenches 608 and 610 may be angled (e.g., about 45 degrees) relative to corresponding edges of the adjacent first and second sides of the active region 602, although embodiments of the invention are not limited to any specific angle. In one or more embodiments, an end of each of the horizontal trenches 610 is aligned with a mesa between adjacent vertical trenches 608, and vice versa, in a “zipper” configuration; that is, corresponding facing ends of the vertical trenches 608 and horizontal trenches 610 may be offset relative to one another. This allows the mesas to be electrically connected to the active region 602. Note, that in FIG. 6, although somewhat difficult to see, there may be a break between respective ends of the vertical trenches 608 and horizontal trenches 610 proximate line 616, forming the zipper portion of the corner structure 600.

With regard to the mesas, it is to be understood that a continuous path along a mesa is not necessarily required for the mesas to be electrically connected to the active region 602. The mesas just need to have a path to a place where they can share electrical connection to the active region 602. For example, in FIG. 6, electrical connection to the active region 602 may be provided through contacts (not explicitly shown) placed inside the guard ring 606. Since the guard ring 606 forms a blocking PN junction, it is of opposite conductivity with respect to an epitaxial doping. Thus, the mesas, which may be formed of epitaxial material, will be of a second conductivity type (e.g., n-type), opposite in polarity to the first conductivity type of the guard ring 606.

The corner structure 600, in one or more embodiments, may further comprise a continuous boundary trench 618 which follows an outside perimeter of the IC device in which the corner structure 600 is formed. While the boundary trench 618 may be optional, it does provide additional benefits. For example, for a RESURF (reduced surface field) structure, the boundary trench 618 may ensure that a bottom potential is at a surface on the outside of the edge termination region, which ensures that the entire voltage is dropped in the defined edge termination region; that is, the trench boundary functions as a traditional channel stopper. For trench photolithography and etch uniformity, multiple “dummy” boundary trenches may be optionally employed.

A further benefit of using this boundary trench 618 is that this trench can also support some voltage and hence improve the voltage blocking performance of the overall edge termination structure in which the corner structure 600 resides. How effective this is may depend on one or more design factors, such as the spacing and/or the width of this trench, among other factors. Note, that this boundary trench 618 is preferably fabricated using the same processing as the edge trenches, but this does not have to be the case, especially if a boundary trench having different dimensions than the edge trenches (e.g., wider, deeper, etc.) is desired.

The boundary trench 618 is preferably, but not necessarily, separated from the vertical and horizontal trenches 608, 610 in the edge termination region 604 by a trench end gap 620. The width of the trench end gap 620 (i.e., spacing between the end of the trenches 608, 610 and the boundary trench 618) may be important. For example, if the trench end gap 620 is too wide (in a plan view), then a bottom potential can reach the surface due to a lack of charge balance in this region. However, a smaller width for the trench end gap 620 can be beneficial in that with a small gap, some additional voltage can be dropped across the last trench, thereby improving breakdown voltage in the device or allowing a narrower edge termination. As the terms are used herein, a “small” gap is intended to refer to a gap size that is less than the mesa width, and a “wide” gap is intended to refer to a gap size that is greater than the mesa width. In one or more embodiments, the trench end gap 620 can be zero (i.e., the outward-facing trenches 608, 610 extend directly into the boundary trench 618).

In terms of function of the trench end gap 620, it is generally desirable to maintain some level of charge balance at the end of the structure, and by having a small gap the level of charge balance in that region can be controlled; if the gap is zero, there may be too much charge (unless the peripheral trench does not contribute materially to the charge balance)—so the trench end gap 620 may function, in some ways, like the gap 612 between the horizontal trenches 610 and the first vertical trench 614. Furthermore, sometimes having a T-junction makes fabrication more problematic; etching and filling this junction is different as it has a wider geometry. Note, that in FIG. 6 the trench is depicted as a continuous curve, while in FIG. 7A the trench is illustrated as a stepped structure to maintain this small gap.

FIGS. 7A and 7B are top plan and cross-sectional views, respectively, depicting at least a portion of an exemplary corner structure 700 for use in an edge termination region of a charge balanced IC device which incorporates other features therein, according to one or more embodiments of the invention; specifically, FIG. 7B is a cross-sectional view of the mesa (i.e., region between two adjacent trenches) of the corner structure 700 taken along line B-B′ shown in FIG. 7A. Similar to the illustrative corner structure 600 shown in FIG. 6, the corner structure 700 includes a p-type guard ring 702 which marks a transition between an active region 704 and an edge termination region 706 in the IC device. The guard ring 702 may be formed, in one or more embodiments, using a p-type implant process.

The active region 704 includes a plurality of charge balancing horizontal trenches 708 (i.e., oriented in an x-axis direction) which extend continuously through the guard ring 702 and into a portion of the edge termination region 706. The edge termination region 706 in the corner structure 700 further includes a plurality of charge balancing vertical trenches 710 (i.e., oriented in a y-axis direction) which are separate and orthogonal to the active region trenches 708. In one or more embodiments, to minimize current crowding of any current flowing within a termination mesa, a portion of at least a subset of the vertical trenches 710 may originate in the active region 704 itself, passing through the guard ring 702 and into the edge termination region 706. It is to be appreciated that embodiments of the invention are not limited to the specific type of material forming the trenches or the direction in which the trenches are oriented.

In a manner similar to the exemplary corner structure 600 shown in FIG. 6, in a corner of the edge termination region 706, the horizontal trenches 708 and the vertical trenches 710 meet at about a 45-degree angle, although embodiments of the invention are not limited to any specific angle, such that an angle less than 45 degrees (e.g., 30 degrees) or greater than 45 degrees (e.g., 60 degrees) may be similarly employed; certain performance characteristics (e.g., charge balance, voltage breakdown, current crowding during avalanche etc.) of the edge termination structure may be controlled through selection of this angle, which in extreme cases may even be selected to be zero or 90 degrees. In one or more embodiments, an end of each of the horizontal trenches 708 is aligned with a mesa between adjacent vertical trenches 710, and vice versa, in a “zipper” configuration. This allows all mesas to be electrically connected to the active region 704.

In one or more embodiments, the illustrative corner structure 700 employs one or more field plates to facilitate distribution of the electric field in the device, among other benefits. Field plates are often used to reduce high electric fields that can occur on the guard ring. Edge termination schemes employing field plates will be known to those skilled in the art. With continued reference to FIGS. 7A and 7B, the corner structure 700 includes a first field plate 712, which is referred to herein as an inner field plate, and a second field plate 714, which is referred to herein as an outer field plate. The inner field plate 712 preferably comprises a conductive material, such as a metal, and is disposed proximate to an upper surface of the active region 704, over the guard ring 702 and active region trenches 708, and into a portion of the edge termination region 706. The outer field plate 714, which also preferably comprises a conductive material (which may the same or a different material compared to the inner field plate), is disposed proximate an upper surface of the edge termination region 706. The outer field plate 714, in one or more embodiments, follows an outer perimeter of the horizontal trenches 708 and vertical trenches 710 in the edge termination region, near an outer edge of the corner structure 700. In practice, it is only the portions of the inner and outer field plates 712, 714 extending beyond the guard ring 702 that function as a field plate in the traditional sense.

In one or more embodiments, the corner structure 700 includes a junction termination extension (JTE) implant 716 formed in at least a portion of the edge termination region 706, proximate an upper surface of the edge termination region. The JTE implant 716 is preferably disposed between the guard ring 702 and an outer periphery of the horizontal and vertical trenches 708, 710 in the edge termination region 706. The JTE implant 716 assists in distributing the voltage laterally across the edge termination region 706, thereby helping to minimize electric field peaks and thus beneficially maximize breakdown voltage in the device. An insulating layer 718 preferably electrically isolates the JTE implant 716 from the inner field plate 712. Optionally, the corner structure 700 may include a boundary trench 720 surrounding a periphery of the IC device, in a manner consistent with the boundary trench 618 shown in FIG. 6. Although only a corner portion of the edge termination structure is depicted in FIG. 7, it is to be understood that the features described in conjunction with FIG. 7 apply similarly to the entire edge termination structure, not just to the corner portion.

It is to be appreciated that a similar effect to a JTE implant can be achieved by employing a layer incorporating fixed charge at a concentration sufficient to invert the silicon surface above the silicon surface.

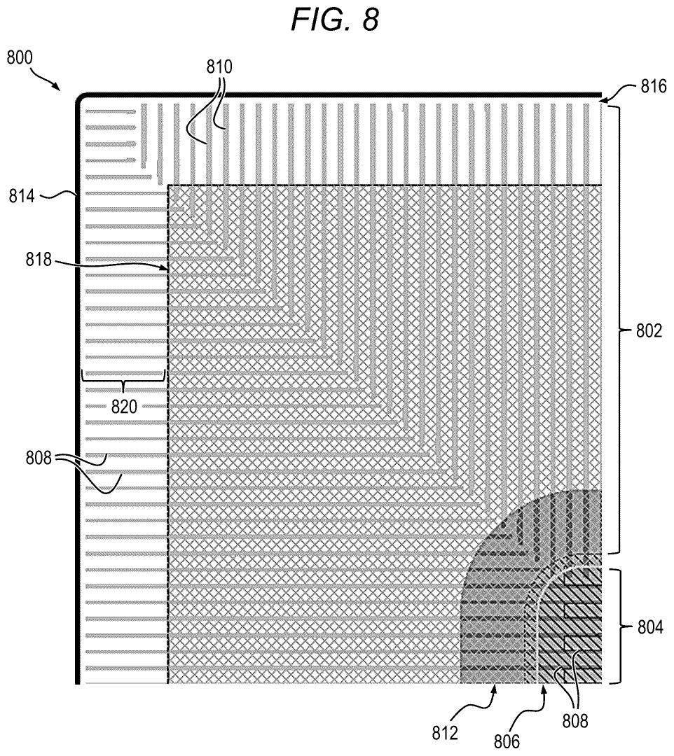

In some embodiments, the IC device includes an edge termination region that utilizes a boundary trench surrounding a perimeter of the device. By way of example only, FIG. 8 is a top plan view depicting at least a portion of an illustrative corner structure 800 for use in an edge termination region 802 of a charge balanced IC device, according to one or more embodiments of the invention. The charge balanced IC device further includes an active region 804 that is distinct from the edge termination region 802, with a guard ring 806 (e.g., p-type guard ring) marking a transition between the active region 804 and the edge termination region 802, in one or more embodiments. Like the exemplary charge balanced IC device shown in FIG. 6, the active region 804 includes a plurality of trenches 808, in this example running in a horizontal direction (i.e., oriented in an x-axis direction). At least a subset of the active region trenches 808 extend continuously beyond the active region 804 and into the edge termination region 802 as shown. The edge termination structure further includes a plurality of vertical trenches 810 (i.e., oriented in a y-axis direction) which are separate and orthogonal to the active region trenches 808. It is to be appreciated that embodiments of the invention are not limited to any specific orientation of the trenches 808, 810.

Similar to the device shown in FIGS. 7A and 7B, an inner field plate 812 may be formed over the active region 804. The inner field plate 812 preferably comprises a conductive material, such as a metal, and is disposed proximate to an upper surface of the active region 804, over the guard ring 806 and plurality of active region trenches 808, and into a portion of the edge termination region 804.

In a manner consistent with the IC device shown in FIG. 6, The edge termination structure 800, in one or more embodiments, further comprises a continuous boundary trench 814 which follows an outside perimeter of the IC device. While the boundary trench 814 is optional, it does provide additional benefits. As previously noted, for a RESURF structure, the boundary trench 814 ensures that a bottom potential is at a surface on the outside of the edge termination region 802, which ensures that the entire voltage is dropped in the defined edge termination region; that is, the boundary trench functions as a traditional channel stopper. For trench photolithography and etch uniformity, multiple “dummy” boundary trenches may be optionally employed.

The boundary trench 814 is preferably separated from the horizontal and vertical trenches 808, 810 in the edge termination region 802 by a trench end gap 816. The width of the trench end gap 816 (i.e., spacing between the end of the trenches 808, 810 and the boundary trench 814) is important. If the trench end gap 816 is too wide, then a bottom potential can reach the surface due to a lack of charge balance. While this can still work effectively, a smaller trench end gap 816 can be beneficial in that with a small gap, some voltage can be dropped across the last trench (i.e., edge termination trenches 808, 810 closest to the boundary trench 814), thereby improving breakdown voltage in the device or providing a narrower edge termination.

In one or more embodiments, a JTE implant 818 may be formed in at least a portion of the edge termination region 802, proximate an upper surface of the edge termination region and covering all or at least a portion of the edge termination trenches 808, 810. The JTE implant 808 is preferably disposed between the guard ring 806 and the boundary trench 814 in the edge termination region 802. The JTE implant 818 assists in distributing the voltage laterally across the edge termination region 802, thereby helping to minimize electric field peaks and thus beneficially maximize breakdown voltage in the device.

A gap 820 between an outer edge of the JTE implant 818 and the boundary trench 814 has been found to play an important role in controlling breakdown voltage in the IC device. If the JTE gap 820 is too small (i.e., the outer edge of the JTE implant 818 is disposed too close to the boundary trench 814), there is a loss of breakdown voltage, but this preferred gap size may depend on other factors as well, such as JTE implant dose and length of the termination region. In one or more embodiments, the JTE gap 820 is formed similar in length to a thickness of the epitaxial layer (e.g., about 10 μm-20 μm for devices with breakdown voltages in a range of about 200-400 volts, or a range of about 0.5× to 2× the epitaxial layer thickness).

With continued reference to FIG. 8, it should also be understood that embodiments of the invention are not limited to the particular shape of the corner structure 800. For example, in some embodiments, the corner structure 800 is square, while in other embodiments, the corner structure is rounded. In simulations and/or experimental testing, there did not seem to be any significant difference in device performance between square or rounded corners, however rounded corners may achieve improved yield since square corners of IC dies often have higher mechanical stress.

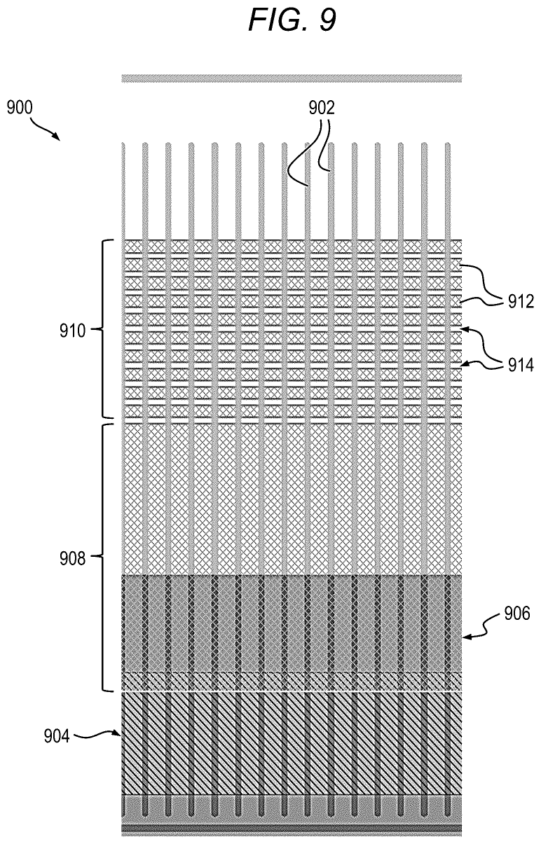

An alternative to using a JTE implant having a substantially constant doping concentration, as in the illustrative IC device shown in FIG. 8, is to use an edge termination region having variable lateral doping (VLD). In a VLD embodiment, the doping concentration of the JTE implant varies across the edge termination region. FIG. 9 is a top plan view depicting at least a portion of an exemplary edge termination region 900 in an IC device that includes a JTE implant that employs VLD, according to one or more embodiments of the invention. With reference to FIG. 9, the edge termination region 900 includes a plurality of edge termination trenches 902 which, in this illustrative embodiment, are oriented vertically. A guard ring 904, which may be formed of a p-type material, defines a transition between an active region (not explicitly shown) in the IC device and the edge termination region 900, in one or more embodiments. The IC device may also include an inner field plate 906 disposed over trenches formed in the active region of the device, in a manner consistent with the inner field plate 712 shown in FIGS. 7A and 7B.

With continued reference to FIG. 9, the JTE implant in the edge termination region 900 of the IC device comprises a first region 908 in which the JTE doping concentration is at full dose (i.e., 100 percent), and a second region 910 in which the JTE doping concentration is reduced relative to the full dose by a prescribed percentage (e.g., 67 percent). Thus, the JTE implant doping concentration varies across the edge termination region 900. There are several different ways in which to achieve VLD in the JTE implant, including using multiple implants. In one or more embodiments, the second JTE implant region 910 creates VLD using small bands of implanted regions 912 separated from one another by bands of non-implanted regions 914 running orthogonal to the edge termination trenches 902. In this manner, the second JTE region 910, on average, will have a lower implant dose compared to the first JTE region 908 having the full implant dose, since a portion of the JTE region 910 is not implanted. Although only two JTE regions 908, 910 are shown in FIG. 9, it is to be appreciated that embodiments of the invention are not limited to any particular number of different JTE regions or corresponding doping concentrations of the respective JTE regions.

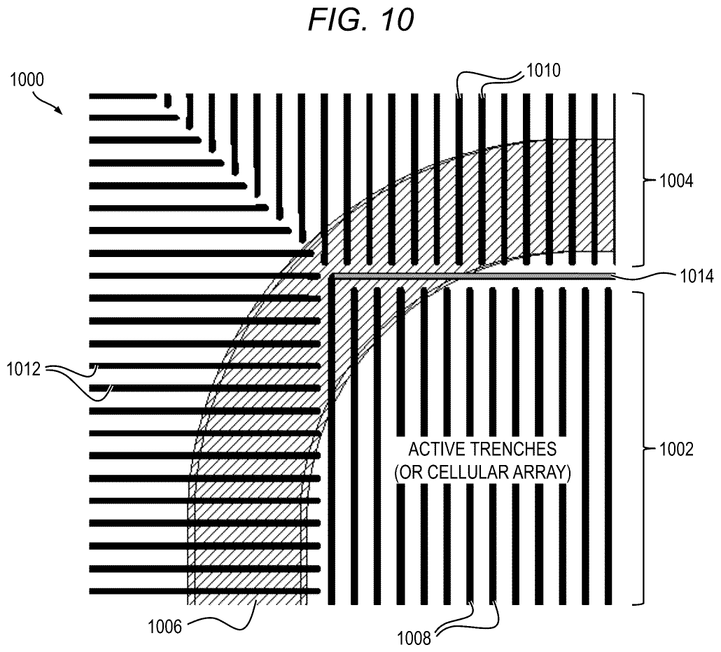

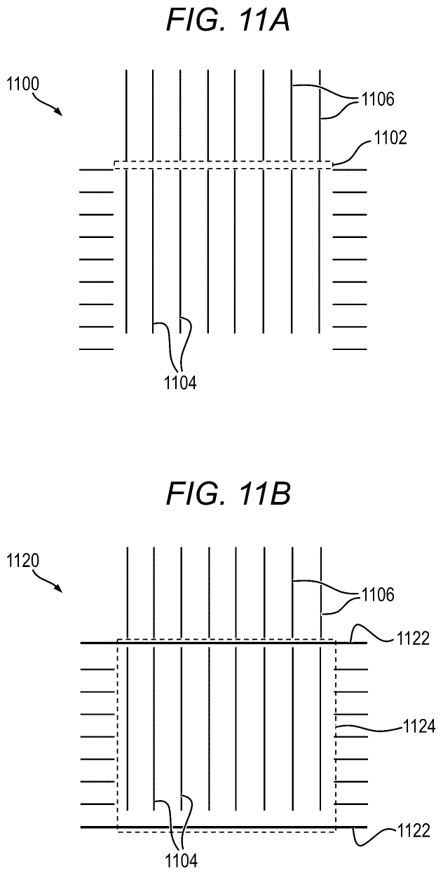

As previously described in connection with the illustrative corner structure 600 shown in FIG. 6, vertical trenches (e.g., 608) formed in the active region pass continuously through the edge termination region. In one or more alternative embodiments, however, the vertical active region trenches may be disconnected from vertical edge termination trenches. By way of example only, FIG. 10 is a top plan view depicting at least a portion of an illustrative corner structure 1000 for use in an edge termination region of a charge balanced IC device, according to one or more embodiments of the invention. The corner structure 1000 includes an active region 1002 and an edge termination region 1004, with a guard ring 1006 (e.g., formed of a p-type material/implant) marking a transition between the active region and edge termination region. As in other embodiments described herein, the guard ring 1006, while perhaps forming at least part of an active element (e.g., a PN diode), is not necessarily considered part of the active region 1002 and may, when disposed on a periphery of the device, be considered to be part of the edge termination region 1004.

The active region 1002 includes a plurality of vertical trenches 1008. The edge termination region 1004 includes a first plurality of trenches 1010, which are vertically oriented (i.e., along a y-axis direction), and a second plurality of trenches 1012, which are oriented orthogonally relative to the vertical trenches 1010 (i.e., horizontally, or along an x-axis direction). In this illustrative embodiment, the vertical trenches 1010 in the edge termination region 1004 are distinct (i.e., disconnected) from the vertical trenches 1008 in the active region 1002.

In the corner structure 1000, a trench 1014 is formed in a break between the vertical active region trenches 1008 and the vertical edge termination region trenches 1010. The trench 1014 is oriented orthogonally (i.e., horizontally) in relation to the vertical trenches 1008, 1010. While the trench 1014 may not be necessary for operation of the IC device, it can assist in charge balancing the region where the break between the vertical active region trenches 1008 and edge termination trenches 1010 occurs.

One beneficial reason to separate the vertical active region trenches 1008 from the vertical edge termination region trenches 1010 is that it allows a different pitch and/or different trench or mesa width to be used for the active region and edge termination region trenches. Edge termination trenches tend to have a lower breakdown voltage than the active region trenches due at least in part to a curvature of the potential lines. Therefore, edge termination design, in one more embodiments, seeks to ensure that the breakdown voltage of the edge termination region is as close as possible to the active region breakdown voltage. A consequence of this breakdown voltage mismatch is that under high current avalanche breakdown, the IC device is vulnerable to failure in the edge termination region (typically, corners are more vulnerable than edges).

In a charge balance structure, the degree of charge balance that is targeted will impact the breakdown voltage. Thus, by having different levels of charge balance in the active and edge termination regions 1002, 1004 (and possibly also different levels of charge balance in the corners of the device), one can ensure that the breakdown voltage in the active region has the lowest breakdown voltage. As an example, the edge termination region can be made “overcharged,” which can increase breakdown voltage under avalanche breakdown thereby ensuring that under avalanche conditions, the breakdown voltage in the edge termination region will reach that of the active region to ensure uniform current sharing. Note, that when a region is “overcharged,” as the term is used herein, it is intended to mean that the charge in the field balancing region (i.e., trench) is greater than the charge in the voltage sustaining/mesa region.

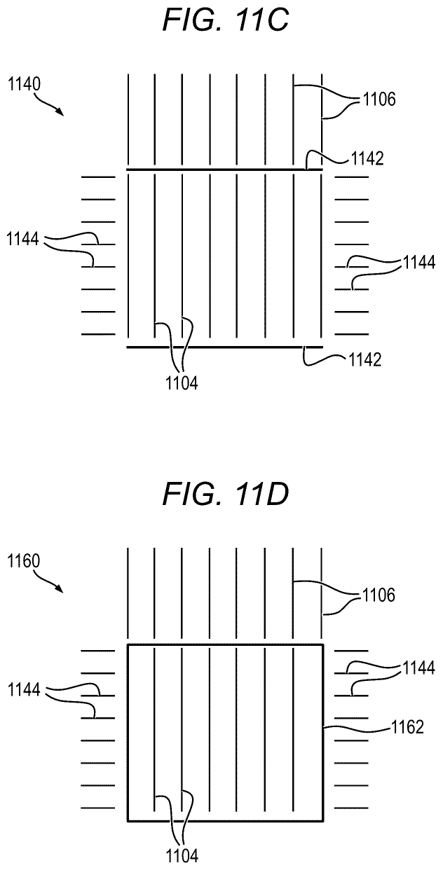

There are various ways to arrange the break between the active region trenches 1008 and the edge termination region trenches 1010 that are contemplated by the present invention. By way of example only and without limitation, FIGS. 11A-11D are top plan views conceptually depicting at least a portion of an illustrative charge balanced IC device utilizing different configurations for forming the break between active region and edge termination region trenches, according to embodiments of the invention. Specifically, In FIG. 11A, an exemplary IC device 1100 is shown wherein the vertical trenches are not continuous between an active region and edge termination region. In this embodiment, there is a simple break 1102 between active region trenches 1104 and edge termination region trenches 1106. This approach has an advantage of a reduced number of fabrication steps, with one disadvantage being a penalty or reduced charge balance where the break occurs (i.e., a region of undercharge where there is more charge in the mesas than in the trenches).

Turning now to FIG. 11B, at least a portion of an exemplary IC device 1120 is shown that includes at least one lateral trench 1122 formed in the break between the vertical active region trenches 1104 and the edge termination region trenches 1106, according to one or more embodiments of the invention. Insertion of the lateral trench 1122 improves charge balance in this break area. In this embodiment, the lateral trench 1122 extends continuously through an active region 1124 and into the surrounding edge termination region of the IC device 1120. Since there is only one trench 1122 separating the vertical trenches 1104, the mesa can still be varied, but it is a bit restrictive for the layout, particularly for those embodiments in which a different pitch between active region trenches and edge termination region trenches is desired.

FIG. 11C depicts at least a portion of an exemplary IC device 1140 which facilitates an easier layout for varying the pitch between active region trenches and edge termination region trenches, according to one or more embodiments of the invention. In this embodiment, at least one lateral trench 1142 is formed in a break between the active region trenches 1104 and the edge termination region trenches 1106. However, unlike the lateral trench configuration in the IC device 1120 shown in FIG. 11B, the lateral trench 1142 does not extend into the edge termination region but rather is broken, such that all edge termination region trenches 1106, including horizontal trenches 1144, are separate from the active region trenches 1104. This configuration facilitates an easier layout for varying the pitch between active region trenches and edge termination region trenches.

With reference now to FIG. 11D, at least a portion of an exemplary IC device 1160 is shown having an electrically isolated active region, according to one or more embodiments of the invention. Specifically, the IC device 1160 includes a continuous boundary trench 1162 which fully surrounds the active region trenches 1104. This arrangement enables the active region to be electrically isolated from the start of the edge termination region. Note, that the mesas in the edge termination region are still electrically shorted to the top surface of the active region via contact to the top metal layer (not explicitly shown, but implied).

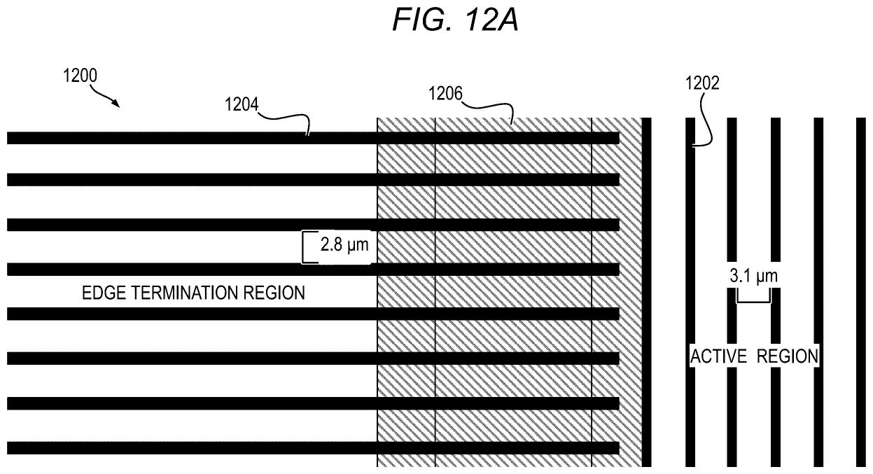

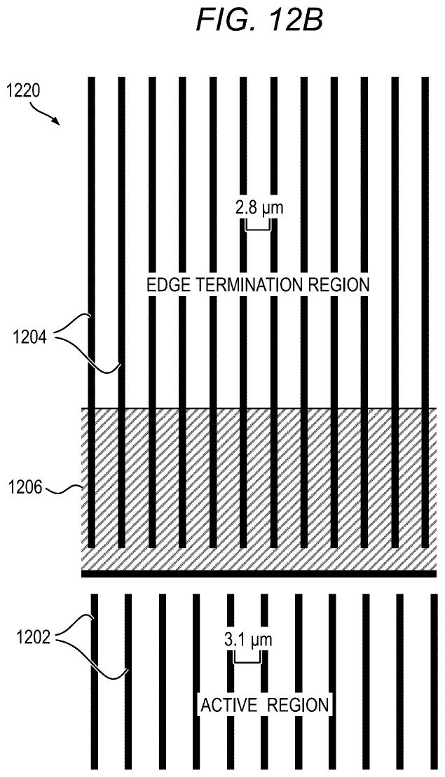

FIGS. 12A and 12B are top plan views depicting an exemplary charge balanced IC device having active region trenches and edge termination region trenches with different pitches, according to one or more embodiments of the invention. In FIG. 12A, the IC device 1200 includes a plurality of active region trenches 1202 and plurality of edge termination region trenches 1204 arranged orthogonal to the active region trenches, with a guard ring 1206 defining a transition between the active and edge termination regions. In this exemplary embodiment, the active region trenches 1202 have a mesa width (between adjacent trenches) of 2.8 μm, and the edge termination region trenches 1204 have a mesa width of 3.1 km. FIG. 12B shows an IC device 1220 that is essentially the same as the IC device 1200 shown in FIG. 12A, but wherein the edge termination trenches 1204 are arranged in the same direction (i.e., parallel with) the active region trenches 1202.

An IC device configured in the manner shown in FIGS. 12A and 12B, with active region trenches and edge termination region trenches having different pitches, beneficially allows for a different level of charge balance in the edge termination region of the device. Furthermore, it is to be appreciated that while the IC devices 1200, 1220 depicted in FIGS. 12A and 12B are formed having edge termination trenches 1204 that are more narrowly spaced relative to the active region trenches 1202, other embodiments of the invention contemplate having the active region trenches more narrowly spaced compared to the edge termination region trenches. By way of example only and without limitation, in one or more embodiments, the mesa width difference between the active region and the edge termination region can be made to vary by up to about 30 percent.

Another factor that can affect breakdown voltage in the IC device is the width and/or depth of the trenches in the active region and/or edge termination region of the device. If the active region trenches do not extend fully through the drift region to the substrate, which is often the case, then achieving deeper trenches in the edge termination region can advantageously increase breakdown voltage of the edge termination structure. In this regard, it is important to note that breakdown voltage is proportional to how far the trenches extend vertically through the drift region. A drift region is generally considered to be the part of a semiconductor device that is used to accommodate the majority of any applied reverse bias and is commonly created by epitaxial growth in vertical devices. In this particular case, it is the region that is sandwiched between the charge balance regions and depicted as the n-type semiconductor material layer 304 in FIGS. 3A-3E (i.e., the n-type portion of the illustrated p-n diode in these figures).

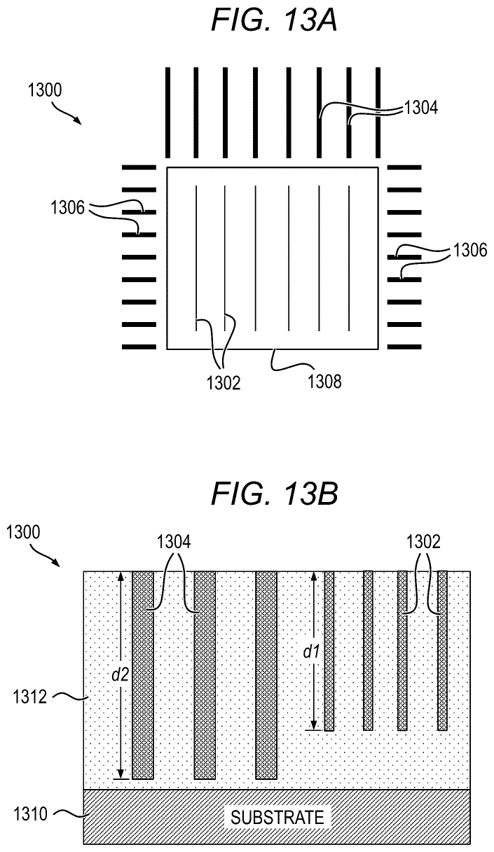

FIGS. 13A and 13B are top plan and cross-sectional views, respectively, depicting at least a portion of an exemplary charge balanced IC device 1300, according to one or more embodiments of the invention. In this embodiment, the IC device 1300 includes an active region comprising a plurality of active region trenches 1302, and an edge termination region comprising a first plurality of edge termination region trenches 1304 oriented in parallel with the active region trenches 1302 and a second plurality of edge termination region trenches 1306 oriented orthogonally to the active region trenches 1302. Optionally, the IC device 1300 includes a continuous boundary trench 1308 which fully surrounds the active region trenches 1302. As previously stated in conjunction with FIG. 11D, this arrangement enables the active region to be electrically isolated from the start of the edge termination region.

With reference in particular to FIG. 13B, the IC device 1300 includes a substrate 1310 and a drift region 1312 formed on an upper surface of at least a portion of the substrate; the active region trenches 1302 and edge termination region trenches 1304 are formed at least partially through the drift region 1312. As previously stated, it is advantageous for the active region trenches to extend fully through the drift region 1312 and to the substrate 1310. However, due at least in part to their narrow width, the active region trenches 1302 will typically not extend to the substrate, but will only a depth d1 through the drift region 1312.

By making the edge termination region trenches 1304 wider, a deeper trench d2 can be achieved in the edge termination region (where d2>d1), thereby beneficially increasing breakdown voltage in the edge termination region. Note, that by using the technology according to one or more embodiments of the invention, it can be shown that trench width can affect the actual charge, so this approach also beneficially enables a level of charge differentiation between the active region and edge termination region, particularly when using atomic layer deposition (ALD) for filling the trenches.

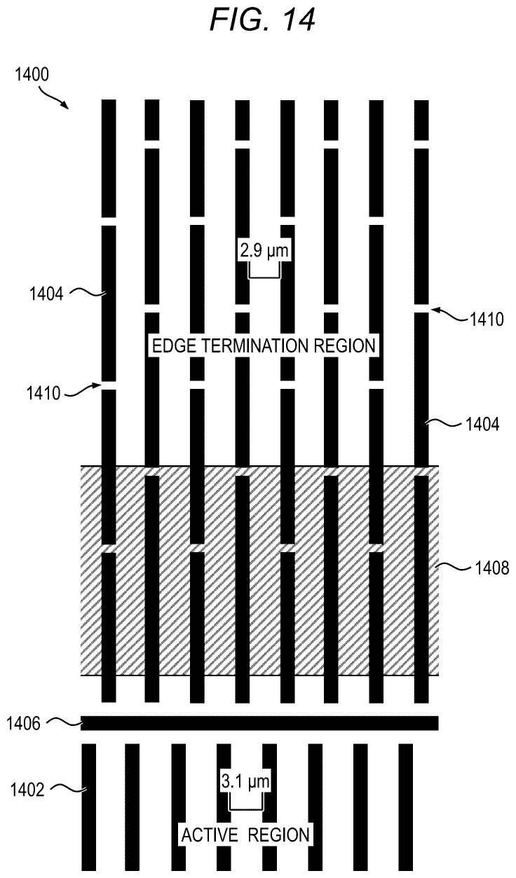

It is to be appreciated that one or more of the unique features according to aspects of the invention can be combined to achieve further performance enhancements. By way of example only and without limitation, the mesa width variation features illustrated in the exemplary charge balanced IC device shown in FIGS. 12A and 12B can be combined with the slotted trench embodiment shown in FIG. 4. An exemplary charge balanced IC device incorporating these features is shown in FIG. 14. More particularly, FIG. 14 is a top plan view depicting at least a portion of an exemplary charge balanced IC device 1400 including mesa width variation and slotted trench features, according to one or more embodiments of the invention.

With continued reference to FIG. 14, the IC device 1400 includes an active region comprising a plurality of trenches 1402 having a first pitch (i.e., spacing between adjacent trenches), for example 3.1 μm. The device 1400 further includes an edge termination region comprising a plurality of trenches 1404 having a second pitch that is different relative to the first pitch, for example 2.9 μm. It is to be understood that embodiments of the invention are not restricted to any specific pitch of the active region trenches 1402 and/or edge termination region trenches 1404. In some embodiments, at least one lateral trench 1406 may optionally be formed in a break between the active region trenches 1402 and the vertical edge termination region trenches 1404. A guard ring 1408 defines a transition between the active region and edge termination region, in accordance with one or more embodiments of the invention.

In order to control the charge balance in the edge termination region relative to the active region, a plurality of slots or breaks 1410 can be placed in at least a subset of the edge termination region trenches 1404, in one or more embodiments. Adding breaks 1410 to the edge termination trenches 1404 may improve susceptibility to failure with high currents by allowing avalanche current flowing in one mesa to spread to neighboring mesas. The breaks 1410 in the edge termination trenches 1404 can also beneficially assist in relieving wafer stress introduced by the deep trenches.

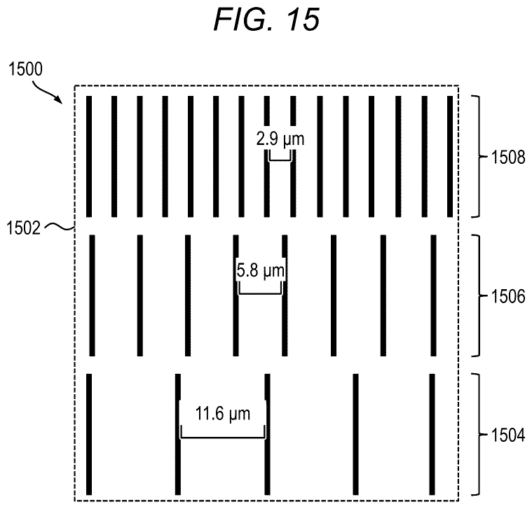

By combining trench breaks with multiple pitch variations in the edge termination region, a graded charge balance can be achieved throughout the edge termination region. FIG. 15 is a top plan view conceptually depicting at least a portion of an exemplary charge balanced IC device 1500 utilizing multiple pitch variations in the exemplary edge termination region, according to one or more embodiments of the invention. Specifically, the IC device 1500 includes an edge termination region 1502 having multiple sets of trenches, each with a different pitch. For example, a first set of edge termination region trenches 1504 has a first pitch (e.g., 11.6 μm), a second set of edge termination region trenches 1506 has a second pitch (e.g., 5.8 μm), and a third set of edge termination region trenches 1508 has a third pitch (e.g., 2.9 μm).

Although in this illustrative embodiment, the trench pitch gets progressively smaller across the edge termination region as the trenches extend out from the active region of the IC device 1500, it is to be appreciated that in some embodiments, an opposite pitch variation scheme may be employed, such that the trench pitch gets progressively wider across the edge termination region as the trenches extend out from the active region.

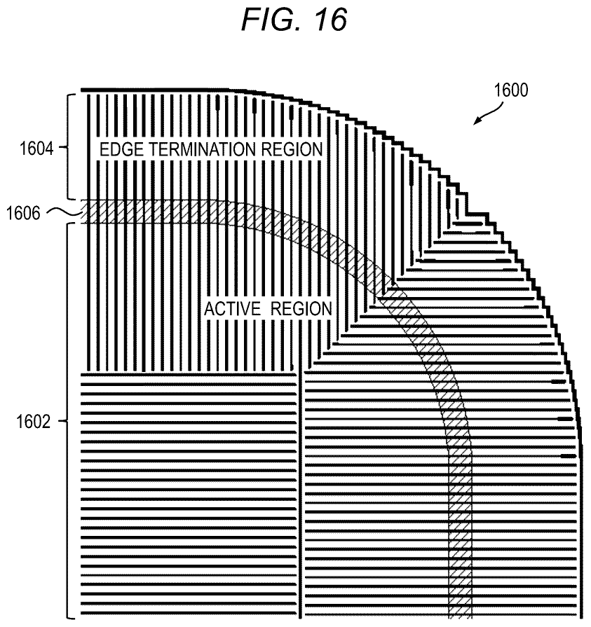

As previously stated in conjunction with FIG. 6, some of the active region trenches (e.g., 608) in the IC device that are aligned along the same direction as a subset of the edge termination region trenches may extend continuously through the guard ring (e.g., 606) and into a portion of the edge termination region. In other embodiments, all outward-facing edge termination region trenches extend continuously through the guard ring and a prescribed distance into the active region, rather than starting on a boundary of the edge termination region. By way of illustration only and without limitation, FIG. 16 is a top plan view depicting at least a portion of an exemplary charge balanced IC device 1600, according to one or more embodiments of the invention. With reference to FIG. 16, the IC device 1600 includes an active region 1602 and an edge termination region 1604, with a guard ring 1606 (e.g., a p-type guard ring) which marks a transition between the active region and the edge termination region in the IC device. The guard ring 1606 may be formed, in one or more embodiments, using a standard implant process.

The trenches in the edge termination region 1604, both those trenches aligned along the same direction as the trenches in the active region 1602 as well as those edge termination region trenches oriented orthogonally relative to the active region trenches, extend continuously through the guard ring 1606 and a prescribed distance into the active region 1602. This configuration allows a larger contact area to the mesas in the active region. Furthermore, this configuration moves any charge imbalance and/or breakdown voltage weakness, caused primarily by the change in trench orientation, into the active region 1602 which provides superior contact and metal coverage, thereby assisting in current spreading and cooling.

The outward-facing trenches in the edge termination region of the exemplary IC device 1600 shown in FIG. 16 (as well as in other illustrative embodiments described herein) include both horizontally and vertically oriented trenches. In a corner of the edge termination region, the horizontal trenches and the vertical trenches meet at about a 45 degree angle, although this angle is not critical. In one or more embodiments, an end of each of the horizontal trenches is preferably aligned with a mesa between adjacent vertical trenches, and vice versa, in a “zipper” configuration. As previously explained, this configuration allows all mesas to be electrically connected to the active region in the IC device. However, the trenches need not be oriented only horizontally and vertically. Rather, alternative embodiments of the invention contemplate that the trenches can extend outwards from the guard ring, tangential to a radius of curvature of the corner structure in the IC device.

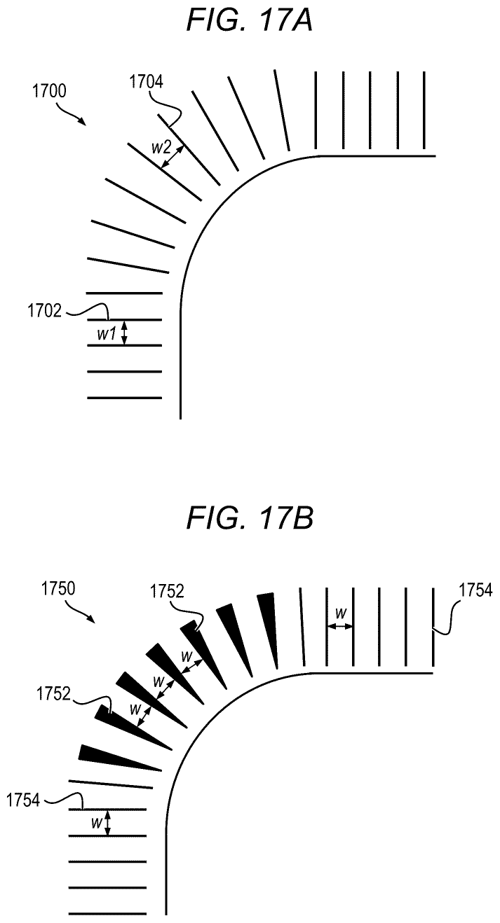

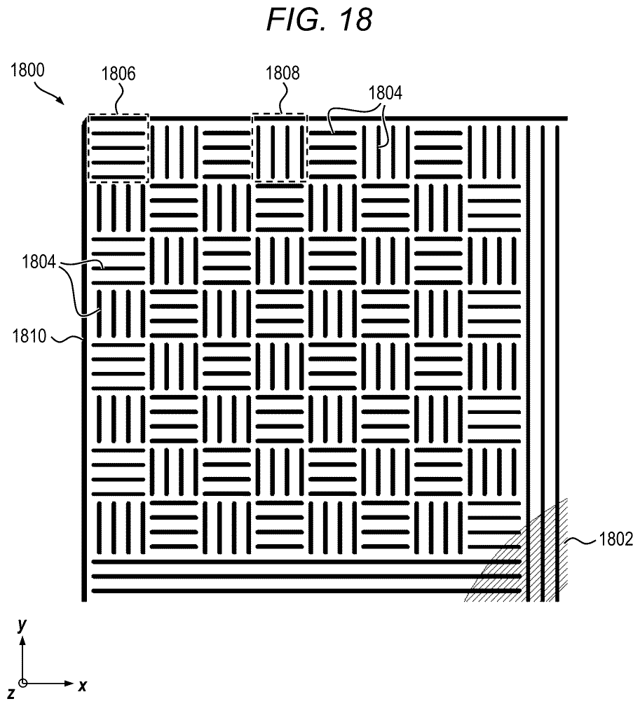

FIGS. 17A and 17B depict two exemplary corner structures, 1700 and 1750, respectively, that employ edge termination region trenches that extend at a tangent to a radius of curvature of a corner structure in a charge balanced IC device, according to embodiments of the invention. In FIG. 17A, the corner structure 1700 employs a plurality of edge termination region trenches 1702 and 1704. Each of the edge termination region trenches 1702, 1704 has the same width. This inherently means that the mesa gets progressively wider in a curved portion of the corner structure 1700, and so the charge balance will vary accordingly in this embodiment. As shown in FIG. 17A, edge termination trenches 1702 disposed along a straight portion of the corner structure 1700 will each have a substantially constant mesa width, w1. With the edge termination region trenches extending outwards tangentially to the corner curvature, trenches 1704 disposed along the curved portion of the corner structure will have an increasing mesa width, w2, where w2>w1. If the mesa becomes too large, additional trenches (not explicitly shown, but implied) can be inserted part way through the edge termination region.

Alternatively, the illustrative corner structure 1750 shown in FIG. 17B utilizes a constant mesa width, w. In order to maintain a constant mesa width even along the curvature of the corner structure 1750, a width of edge termination trenches 1752 disposed along the curved portion of the corner structure must progressively increase compared to edge termination region trenches 1754 disposed along the straight portion of the corner structure.

In one or more embodiments of the invention, another alternative to the “zipper” corner configuration described, for example, in connection with FIG. 6, includes what is referred to herein as a “parquet” corner configuration. By way of example only and without limitation, FIG. 18 is a top plan view illustrating at least a portion of an exemplary parquet corner structure 1800 utilized in an edge termination region of a charge balanced IC device, according to one or more embodiments of the invention. The parquet corner structure 1800 does not necessarily follow the philosophy of using outward-facing trenches in the edge termination region of the IC device. However, the parquet configuration does follow the principle of ensuring that every mesa within the edge termination region is directly connected to the active region surface.

With reference to FIG. 18, a guard ring 1802, which may be a p-type guard in some embodiments, defines a transition between an active region and an edge termination region in the IC device. The parquet corner structure 1800, which is disposed in the edge termination region of the device, includes a plurality of edge termination region trenches 1804 arranged into at least a first group of horizontally oriented trenches 1806 (i.e., extending in an x-axis direction) and a second group of vertically oriented trenches 1808 (i.e., extending in a y-axis direction). The first and second groups of trenches 1806, 1808 may be distributed throughout the corner structure 1800 such that the trenches in any two adjacent groups of trenches are orthogonally oriented relative to one another. Optionally, a continuous boundary trench 1810 may be formed which follows an outside perimeter of the IC device.

Since the corners of the IC device often exhibit lower breakdown voltage compared to other areas of the device, one objective in designing the parquet corner structure 1800 is to ensure that a resistance of the current path in the corner structure is higher than in the other areas of the device. This resistance “ballasting” approach means that there will be a voltage drop across these higher resistance paths, thereby increasing the breakdown voltage at higher currents such that the breakdown voltage in the other areas of the device will be reached.

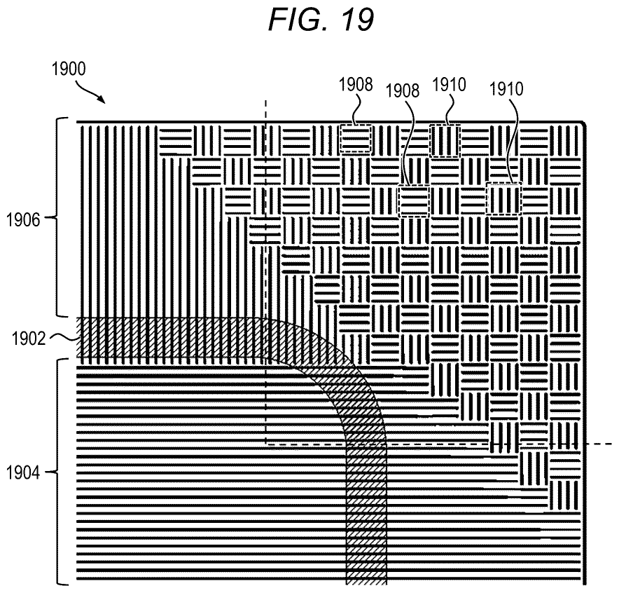

The parquet corner structure 1800 is designed to replace the zipper corner configuration previously described, but from a design perspective the corner is really based on the curvature of the guard ring 1802. Therefore, performance enhancements can be achieved through improved “ballasting” for the whole corner structure and beyond using an extended parquet corner configuration. For instance, FIG. 19 is a top plan view depicting at least a portion of an exemplary extended parquet cornet structure 1900 utilized in an edge termination region of a charge balanced IC device, according to one or more embodiments of the invention. The IC device includes a guard ring 1902, which may be, for example, a p-type guard ring, which marks a transition between an active region 1904 and an edge termination region 1906 in the IC device.

Like the parquet corner structure 1800 shown in FIG. 18, the extended parquet corner structure 1900 comprises a plurality of edge termination region trenches arranged into at least two groups of trenches that are oriented orthogonally relative to one another. In this illustrative embodiment, a first group of trenches 1908 includes a plurality of horizontally oriented trenches, and a second group of trenches 1910 includes a plurality of vertically oriented trenches. It is to be appreciated, however, that embodiments of the invention are not limited to the specific absolute orientation of the trenches. The two groups of trenches 1908, 1910 are arranged such that the trenches in any two adjacent groups of trenches are oriented orthogonally to one another.

In the extended parquet corner structure 1900, outward-facing trenches are modified compared to the arrangement shown in FIG. 18. More particularly, in the illustrative parquet corner structure 1900 embodiment of FIG. 19, the outward-facing trenches close to the corner are shortened to allow a gradual change from the parquet construction to the outward-facing trench construction. One advantage of this approach is that for the exemplary structure 1800 shown in FIG. 18, all current flow in the corner will converge at a small region on the guard ring, while for the illustrative structure 1900 shown in FIG. 19, there are multiple current paths which will prevent any current flow from converging at a single point.

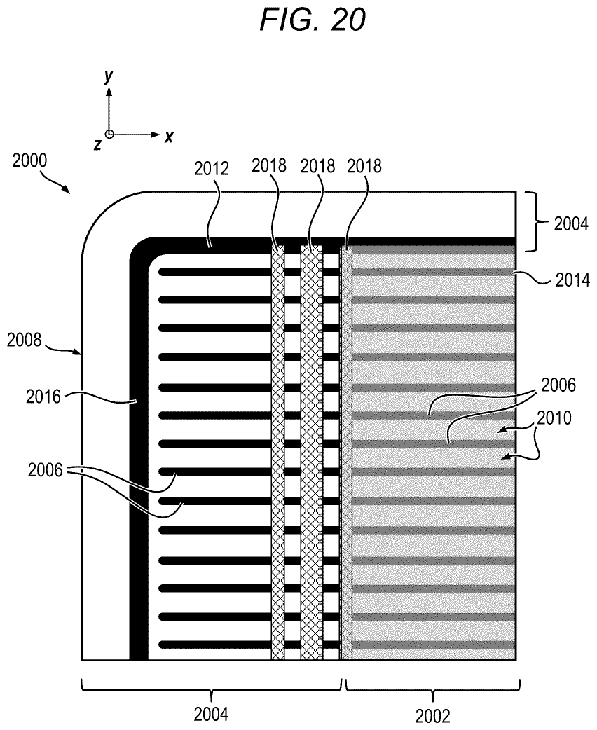

FIG. 20 is a top plan view depicting at least a portion of an exemplary charge balanced IC device 2000 having an enhanced edge termination structure, according to one or more embodiments of the invention. With reference to FIG. 20, the IC 2000 includes an active region 2002 in which one or more active electrical elements/devices (e.g., Schottky diode, MOSFET device, etc.) may be formed, and an edge termination region 2004 surrounding the active region 2002. The edge termination region 2004 may not comprise any active electrical devices/elements therein. The active region 2002 may include a plurality of charge balance regions, which in some embodiments may be implemented as trenches 2006. In this illustrative embodiment, the charge balance trenches 2006 may extend horizontally (i.e., in an x-axis direction, parallel to an upper of a substrate (not explicitly shown, but implied) in which the trenches 2006 are formed) and continuously, in the same orientation, through the active region 2002 and into the edge termination region 2004. Thus, the charge balance trenches 2006, from the perspective of a left side 2008 (and right side, not explicitly shown) of the IC device 2000, may be outwards-facing structures that are perpendicular to an edge of the IC device 2000 (e.g., left side 2008) adjacent to an end of the trenches 2006.

In one or more embodiments, each of at least a subset of the charge balance trenches 2006 may be at least partially filled with a high-k insulating material (although the charge balance trenches 2006 may alternatively comprise a semiconductor material, in other embodiments) and is spaced laterally (in the y-axis direction) from adjacent trenches by a semiconductor mesa 2010 (e.g., in a manner consistent with the arrangement of the trenches 206 and mesas 208 shown in FIG. 2) to achieve charge balance in the IC device 2000; the trenches 2006 are electrically isolated from the mesas 2010 between adjacent trenches 2006.

The illustrative IC device 2000 may include a termination structure on a top edge (and a bottom edge, not explicitly shown) of the IC device 2000 in a y-axis direction intersecting the x-axis direction. In some embodiments, the top edge termination structure may comprise a single wide trench 2012 (i.e., a top edge termination trench) extending along a periphery of the IC device 2000 in the x-axis direction, parallel to the charge balance trenches 2006. The top edge termination trench 2012 may be adjacent to a topmost one of the charge balance trenches 2014 in the y-axis direction. The IC device 2000 may further include a boundary trench 2016 extending in a y-axis direction along a left side 2008 of the IC device, between the top edge termination trench 2012 and a bottom edge termination trench (not explicitly shown), perpendicular to the charge balance trenches 2006 and top edge termination trench 2012.

It is to be appreciated that, although not explicitly shown in FIG. 20, each of at least a subset of the charge balance trenches 2006 may incorporate slots (i.e., gaps, spaces, or the like), consistent with the slots 410 in the trenches 406 shown in FIG. 4. These slots may facilitate current flow in the edge termination region 2004 and ensure that there is a current path for all parts of the edge termination region 2004 to the top surface (in a z-axis direction, perpendicular to the x-axis and y-axis directions) of the active region 2002.

In some embodiments, one or more JTE implants 2018 may be formed in at least a portion of the edge termination region 2004, proximate an upper surface of the edge termination region (in the z-axis direction) and covering all or at least a portion of the trenches 2006. The JTE implants 2018 may be disposed between the top edge termination trench 2012 and the bottom edge termination trench (not explicitly shown) and extending in the y-axis direction in the edge termination region 2004. As previously described, the JTE implants 2018 may assist in distributing the voltage laterally across the edge termination region 2004 (i.e., in the x-axis direction and/or y-axis direction), thereby helping to minimize electric field peaks and thus maximize breakdown voltage in the IC device 2000.

Although not explicitly shown for enhanced clarity, a conductive layer (e.g., metal) may be formed over at least a subset of portions of the charge balance trenches 2006 in the edge termination region 2004 in the IC device 2000. In one or more embodiments, the conductive layer may cover the entire edge termination region 2004, including the top edge termination trench 2012 and the bottom edge termination trench (not explicitly shown), the left side boundary trench 2016 and right side boundary trench (not explicitly shown), the JTE implants 2018, and at least the portions of the charge balance trenches 2006 extending into the edge termination region 2004. The metal layer may serve as a field plate configured to facilitate the distribution of electric fields in the IC device 2000 for increasing breakdown voltage in the device, among other benefits.

Although the overall fabrication methods and the structures formed thereby are entirely novel, certain individual processing steps required to implement the method may utilize conventional semiconductor fabrication techniques and conventional semiconductor fabrication tooling. These techniques and tooling will already be familiar to those having ordinary skill in the relevant arts given the teachings herein. Moreover, many of the processing steps and tooling used to fabricate semiconductor devices are also described in a number of readily available publications, including, for example: P. H. Holloway et al., Handbook of Compound Semiconductors: Growth, Processing, Characterization, and Devices, Cambridge University Press, 2008; and R. K. Willardson et al., Processing and Properties of Compound Semiconductors, Academic Press, 2001, which are both hereby incorporated herein by reference in their entireties for all purposes. It is emphasized that while some individual processing steps are set forth herein, those steps are merely illustrative, and one skilled in the art may be familiar with several equally suitable alternatives that would also fall within the scope of the invention.

It is to be appreciated that the various layers and/or regions shown in the accompanying figures may not be drawn to scale. Furthermore, one or more semiconductor layers of a type commonly used in such semiconductor devices may not be explicitly shown in a given figure to facilitate a clearer description. This does not imply that the semiconductor layer(s) not explicitly shown are omitted in the actual device.

In one or more embodiments, formation of the exemplary device structures described herein may involve deposition of certain materials and layers by physical vapor deposition (PVD), chemical vapor deposition (CVD), atomic layer deposition (ALD), molecular beam epitaxy (MBE), or any of the various modifications thereof, including, for example, plasma-enhanced chemical vapor deposition (PECVD), metal-organic chemical vapor deposition (MOCVD), low pressure chemical vapor deposition (LPCVD), electron-beam physical vapor deposition (EB-PVD), and plasma-enhanced atomic layer deposition (PE-ALD). The depositions can be epitaxial processes, and the deposited material can be crystalline. In one or more embodiments, formation of a layer can be achieved using a single deposition process or multiple deposition processes, where, for example, a conformal layer is formed by a first process (e.g., ALD, PE-ALD, etc.) and a fill is formed by a second process (e.g., CVD, electrodeposition, PVD, etc.); the multiple deposition processes can be the same or different.

As used herein, the term “semiconductor” may refer broadly to an intrinsic semiconductor material that has been doped, that is, into which a doping agent has been introduced, giving it different electrical properties than the intrinsic semiconductor material, or it may refer to intrinsic semiconductor material that has not been doped. Doping may involve adding dopant atoms to an intrinsic semiconductor material, which thereby changes electron and hole carrier concentrations of the intrinsic semiconductor material at thermal equilibrium. Dominant carrier concentration in an extrinsic semiconductor material determines the conductivity type of the semiconductor material.

The term “metal,” as used herein, is intended to refer to any electrically conductive material, regardless of whether the material is technically defined as a metal from a chemistry perspective or not. Thus “metals” as used herein will include such materials as, for example, aluminum, copper, silver, gold, etc., and will include such materials as, for example, graphene, germanium, gallium arsenide, highly-doped polysilicon (commonly used in most MOSFET devices), etc. This is to be distinguished from the definition of a “metal” from a physics perspective, which usually refers to those elements having a partially filled conduction band and having lower resistance toward lower temperature.

The term “gate” as used herein may refer broadly to a structure used to control output current (i.e., flow of carriers in a channel) of a semiconducting device through the application of electrical or magnetic fields.

The term “crystalline” as used herein may refer broadly to any material that is single-crystalline or multi-crystalline (i.e., polycrystalline).

The term “non-crystalline material” generally refers to any material that is not crystalline, including any material that is amorphous, nano-crystalline, or micro-crystalline.

The term “intrinsic” as used herein may refer broadly to any material which is substantially free of dopant atoms, or material in which the concentration of dopant atoms is less than a prescribed amount, such as, for example, about 10¹⁵ atoms/cm³.

As used herein, the term “insulating” may generally denote a material having a room temperature conductivity of less than about 10⁻¹⁰ (Ω-m)⁻¹.

As used herein, “p-type” may refer broadly to the addition of impurities to an intrinsic semiconductor material that creates deficiencies of valence electrons. In a silicon-containing material, examples of p-type dopants (i.e., impurities) may include, but are not limited to, boron, aluminum, gallium and indium.

As used herein, “n-type” may refer broadly to the addition of impurities that contribute free electrons to an intrinsic semiconductor material. In a silicon-containing material, examples of n-type dopants may include, but are not limited to, antimony, arsenic and phosphorous.

The term “gate dielectric” as used herein may refer broadly to insulating materials such as, but not limited to, silicon oxide, silicon nitride, silicon oxynitride, boron nitride, high-dielectric constant (high-k) materials, or any combination of these materials. Non-limiting examples of high-k materials may include, for example, metal oxides, such as hafnium oxide, hafnium silicon oxide, hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate, ceramics, etc. High-k materials may further include dopants such as lanthanum, aluminum, etc.

It will also be understood that when an element such as a layer, region or substrate is referred to as being “atop,” “above,” “on” or “over” another element, it is broadly intended that the element be in direct contact with the other element or intervening elements may also be present. In contrast, when an element is referred to as being “directly on” or “directly over” another element, it is intended that there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Furthermore, positional (i.e., directional) terms such as “above,” “below,” “upper,” “lower,” “under,” and “over” as may be used herein, are intended to indicate relative positioning of elements or structures to each other as opposed to absolute position. Thus, for example, if a particular element is described as having a “top surface,” that same top surface may be considered to be a “bottom surface” of the element when that element is rotated by 180 degrees.

At least a portion of the techniques of the present invention may be implemented in an integrated circuit. In forming integrated circuits, identical die are typically fabricated in a repeated pattern on a surface of a semiconductor wafer. Each die includes a device described herein, and may include other structures and/or circuits. The individual die are cut or diced from the wafer, then packaged as an integrated circuit. One skilled in the art would know how to dice wafers and package die to produce integrated circuits. Any of the exemplary structures illustrated in the accompanying figures, or portions thereof, may be part of an integrated circuit. Integrated circuits so manufactured are considered part of this invention.

Those skilled in the art will appreciate that the exemplary structures discussed above can be distributed in raw form (i.e., a single wafer having multiple unpackaged chips), as bare dies, in packaged form, or incorporated as parts of intermediate products or end products that benefit from having enhanced edge termination structures therein (e.g., power IC devices) formed in accordance with one or more embodiments of the invention.

An integrated circuit in accordance with aspects of the present disclosure can be employed in essentially any application and/or electronic system involving enhanced breakdown voltage structures, such as, but not limited to, power MOSFET devices, Schottky diodes, etc. Suitable systems and applications for implementing embodiments of the invention may include, but are not limited to, AC-DC and DC-DC conversion, motor control, and power supply OR-ing (“OR-ing” is a particular type of application that parallels multiple power supplies to one common power bus in a redundant power system architecture). Systems incorporating such integrated circuits are considered part of this invention. Given the teachings of the present disclosure provided herein, one of ordinary skill in the art will be able to contemplate other implementations and applications of embodiments of the invention.

The illustrations of embodiments of the invention described herein are intended to provide a general understanding of the various embodiments, and they are not intended to serve as a complete description of all the elements and features of apparatus and systems that might make use of the structures and semiconductor fabrication methodologies described herein. Many other embodiments will become apparent to those skilled in the art given the teachings herein; other embodiments are utilized and derived therefrom, such that structural and logical substitutions and changes can be made without departing from the scope of this disclosure. The drawings are also merely representational and are not necessarily drawn to scale. Accordingly, the specification and drawings are to be regarded in an illustrative rather than a restrictive sense.

Embodiments of the invention are referred to herein, individually and/or collectively, by the term “embodiment” merely for convenience and without intending to limit the scope of this application to any single embodiment or inventive concept if more than one is, in fact, shown. Thus, although specific embodiments have been illustrated and described herein, it should be understood that an arrangement achieving the same purpose can be substituted for the specific embodiment(s) shown; that is, this disclosure is intended to cover any and all adaptations or variations of various embodiments. Combinations of the above embodiments, and other embodiments not specifically described herein, will become apparent to those of skill in the art given the teachings herein.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof.

The corresponding structures, materials, acts, and equivalents of all means or step-plus-function elements in the claims below are intended to include any structure, material, or act for performing the function in combination with other claimed elements as specifically claimed. The description of the various embodiments has been presented for purposes of illustration and description, but is not intended to be exhaustive or limited to the forms disclosed. Many modifications and variations will be apparent to those of ordinary skill in the art without departing from the scope and spirit of the invention. The embodiments were chosen and described in order to best explain the principles of the invention and the practical application, and to enable others of ordinary skill in the art to understand the various embodiments with various modifications as are suited to the particular use contemplated.

The abstract is provided to comply with 37 C.F.R. § 1.72(b), which requires an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the appended claims reflect, inventive subject matter lies in less than all features of a single embodiment. Thus the following claims are hereby incorporated into the Detailed Description, with each claim standing on its own as separately claimed subject matter.

Given the teachings of embodiments of the invention provided herein, one of ordinary skill in the art will be able to contemplate other implementations and applications of the techniques of embodiments of the invention. Although illustrative embodiments of the invention have been described herein with reference to the accompanying drawings, it is to be understood that embodiments of the invention are not limited to those precise embodiments, and that various other changes and modifications are made therein by one skilled in the art without departing from the scope of the appended claims.

What is claimed is:

1. An edge termination structure for use in a charge balanced semiconductor device, the edge termination structure comprising:
a plurality of charge balance edge termination trenches formed in an edge termination region of the semiconductor device, the change balance edge termination trenches extending outwardly from an active region of the semiconductor device toward the edge termination region on at least two sides of the active region when viewed in a plan view, the charge balance edge termination trenches being orthogonal to an edge of the active region; and
a plurality of semiconductor mesa regions, each of at least a subset of the semiconductor mesa regions being between adjacent charge balance edge termination trenches.

2. The edge termination structure according to claim 1, wherein at least a subset of the plurality of charge balance edge termination trenches includes one or more slots therein, the slots configured to facilitate current flow in the edge termination region and to ensure that there is an electrical connection for all parts of the edge termination region to a top surface of the active region.

3. The edge termination structure according to claim 2, wherein the slots are configured such that slots formed in one of the charge balance edge termination trenches are not aligned, when viewed in a plan view, with slots formed in an adjacent one of the charge balance edge termination trenches.

4. The edge termination structure according to claim 1, wherein the edge termination structure is configured such that a first amount of charge balance in the edge termination region is different relative to a second amount of charge balance in the active region of the semiconductor device.

5. The edge termination structure according to claim 1, wherein a spacing between at least a subset of adjacent charge balance edge termination trenches in the edge termination region, when viewed in a plan view, is different relative to a spacing between adjacent charge balance trenches in the active region of the semiconductor device.

6. The edge termination structure according to claim 1, further comprising a boundary trench extending around a periphery of the semiconductor device.

7. The edge termination structure according to claim 1, wherein a first subset of the plurality of charge balance edge termination trenches is oriented in a first direction and at least a second subset of the plurality of charge balance edge termination trenches is oriented in a second direction, the second direction being different than the first direction.

8. The edge termination structure according to claim 1, further comprising a field plate above at least a subset of the plurality of charge balance edge termination trenches, the field plate configured to distribute an electric field in the semiconductor device.

9. The edge termination structure according to claim 1, further comprising a guard ring defining a transition between the active region and the edge termination region.

10. The edge termination structure according to claim 1, wherein each of at least a subset of the plurality of semiconductor mesa regions comprises at least one of an n-type semiconductor material or a p-type semiconductor material.

11. The edge termination structure according to claim 1, wherein each of at least a subset of the plurality of charge balance edge termination trenches comprises a fixed charged layer.

12. The edge termination structure according to claim 1, wherein the plurality of charge balance edge termination trenches are configured to extend outwardly from the active region toward the edge termination region on at least two adjacent sides of the active region, such that a first subset of the plurality of charge balance edge termination trenches on a first side of the active region is orthogonal to a second subset of the plurality of charge balance edge termination trenches on a second side of the active region adjacent to the first side.

13. The edge termination structure according to claim 1, further comprising a boundary trench extending along a periphery of the semiconductor device, when viewed in a plan view, parallel to the plurality of charge balance edge termination trenches.

14. The edge termination structure according to claim 1, further comprising one or more corner structures, each of the corner structures being configured to provide an interface at which ends of a first subset of the plurality of charge balance edge termination trenches extending in a first direction from a first side of the active region meet corresponding facing ends of a second subset of the plurality of charge balance edge termination trenches extending in a second direction from a second side of the active region adjacent to the first side of the active region.

15. The edge termination structure according to claim 14, wherein the interface is configured to be at a prescribed angle relative to an edge of the first and second sides of the active region.

16. The edge termination structure according to claim 14, wherein the ends of the first subset of the plurality of charge balance edge termination trenches are offset relative to the corresponding facing ends of the second subset of the plurality of charge balance edge termination trenches.

17. The edge termination structure according to claim 14, wherein the interface is configured such that an end of each of the first subset of the plurality of charge balance edge termination trenches is aligned with a mesa between adjacent trenches in the second subset of the plurality of charge balance edge termination trenches, and vice versa.

18. The edge termination structure according to claim 1, further comprising one or more corner structures, each of the corner structures including a first group of charge balance edge termination trenches extending in a first direction perpendicular to a first side of the edge termination region adjacent to the corner structure, and a second group of charge balance edge termination trenches extending in a second direction perpendicular to the first direction, wherein the first and second groups of charge balance edge termination trenches are distributed throughout the corner structure such that the charge balance edge termination trenches in any two adjacent groups of trenches are orthogonally oriented relative to one another.

19. The edge termination structure according to claim 1, wherein each of at least a subset of the plurality of semiconductor mesa regions forms an electrically conductive structure, and each of at least a subset of the plurality of charge balance edge termination trenches forms an electrically non-conductive structure.

20. The edge termination structure according to claim 1, wherein the plurality of charge balance edge termination trenches extend outwardly from the active region toward the edge termination region on at least three sides of the active region, when viewed in a plan view.

21. The edge termination structure according to claim 1, wherein the plurality of charge balance edge termination trenches extend outwardly from the active region toward the edge termination region on all four sides of the active region, when viewed in a plan view.

22. A charge balanced semiconductor device, comprising:
an active region including at least one active element therein; and
an edge termination region extending around the active region when viewed in a plan view, the edge termination region including at least one edge termination structure comprising:
a plurality of charge balance edge termination trenches, the change balance edge termination trenches extending outwardly from the active region of the semiconductor device toward the edge termination region on at least two sides of the active region, the charge balance edge termination trenches being orthogonal to an edge of the active region; and
a plurality of semiconductor mesa regions, each of the semiconductor mesa regions being between adjacent charge balance edge termination trenches.

23. The semiconductor device according to claim 22, wherein each of at least a subset of the plurality of semiconductor mesa regions in the at least one edge termination structure is an electrically conductive structure, and each of at least a subset of the plurality of charge balance edge termination trenches in the at least one edge termination structure is an electrically non-conductive structure.

24. The semiconductor device according to claim 22, wherein the plurality of charge balance edge termination trenches in the at least one edge termination structure extend outwardly from the active region toward the edge termination region on at least three sides of the active region when viewed in a plan view.

25. The semiconductor device according to claim 22, wherein the plurality of charge balance edge termination trenches extend outwardly from the active region toward the edge termination region on all four sides of the active region.

26. The semiconductor device according to claim 22, further comprising:
a guard ring of a first conductivity type, the guard ring extending around the active region when viewed in a plan view and defining a boundary between the active region and the edge termination region in the semiconductor device,
wherein the plurality of semiconductor mesa regions are of a second conductivity type opposite in polarity to the first conductivity type.

27. A method of forming an edge termination structure in a charge balanced semiconductor device, the method comprising:
forming a plurality of charge balance edge termination trenches in an edge termination region of the semiconductor device, the change balance edge termination trenches being configured to extend outwardly from an active region of the semiconductor device toward the edge termination region on at least two sides of the active region, the charge balance edge termination trenches being orthogonal to an edge of the active region; and
forming a plurality of semiconductor mesa regions, each of the semiconductor mesa regions being between adjacent charge balance edge termination trenches.

28. The method according to claim 27, wherein forming the plurality of charge balance edge termination trenches comprises forming the plurality of charge balance edge termination trenches extending outwardly from the active region toward the edge termination region on at least three sides of the active region.

29. The method according to claim 27, wherein forming the plurality of charge balance edge termination trenches comprises forming the plurality of charge balance edge termination trenches extending outwardly from the active region toward the edge termination region on all four sides of the active region.

30. A method of forming a charge balanced semiconductor device, the method comprising:
forming an active region including at least one active element therein; and
forming an edge termination region at least partially surrounding the active region when viewed in a plan view, the edge termination region including at least one edge termination structure, wherein forming the edge termination structure further comprises:
forming a plurality of charge balance edge termination trenches in an edge termination region of the semiconductor device, the change balance edge termination trenches being configured to extend outwardly from an active region of the semiconductor device toward the edge termination region on at least two sides of the active region, the charge balance edge termination trenches being orthogonal to an edge of the active region; and
forming a plurality of semiconductor mesa regions, each of the semiconductor mesa regions being between adjacent charge balance edge termination trenches.
